(19) United States
(12) Patent Application Publication
(10) Pub. No.: US 2018/0233770 A1
(43) Pub. Date: Aug. 16, 2018

(54) METAL FLUORIDE COATED LITHIUM INTERCALATION MATERIAL AND METHODS OF MAKING SAME AND USES THEREOF

(71) Applicant: Technio Research & Development Foundation Limited, Haifa (IL)

(72) Inventors: Yair EIN-ELI, Haifa (IL); Alexander KRAYTSBERG, Yokneam (IL); Haika DREZNER, Afula (IL)

(21) Appl. No.: 15/749,538

(22) PCT Filed: Aug. 8, 2016
(86) PCT No.: PCT/IL2016/050865

§ 371 Date: Feb. 1, 2018

Related U.S. Application Data
(60) Provisional application No. 62/203,542, filed on Aug. 11, 2015.

(51) Int. Cl. H01M 10/0525; C23C 16/455; C23C 16/30; C23C 16/10; H01M 4/1393; H01M 4/1391; H01M 4/131; H01M 4/133; H01M 4/62; H01M 2/14

(52) U.S. Cl. CPC H01M 10/0525; C23C 16/45525; C23C 16/30; C23C 16/10; H01M 4/1393; H01M 2004/021; H01M 4/131; H01M 4/133; H01M 4/621; H01M 2/14; H01M 4/1391

(57) ABSTRACT

Provided herein is a method of reducing the charge/discharge capacity fade rate of a rechargeable lithium-ion battery (LIB) during cycling, and extending the life and the number of discharge/recharge cycles thereof, effected by coating particles of lithium intercalation materials used for making the electrodes of the LIB, with a uniform layer of a metal fluoride effected by atomic layer deposition (ALD). Also provided are coated particulate lithium intercalation materials, electrodes and lithium-ion batteries having electrodes made with particulate lithium intercalation materials coated with a uniform later of a metal fluoride using ALD.

### FIELD AND BACKGROUND OF THE INVENTION

The present invention, in some embodiments thereof, relates to electrochemistry, and more particularly, but not exclusively, to a modified particulate lithium intercalation electrode material and a method of reducing a capacity fade rate during discharge/recharge cycling of a lithium-ion rechargeable battery.

In the 1970s-1980s, the concept of a Li-ion secondary battery (rechargeable cell) has been demonstrated based on the substitution of a Li metal anode with Li-ion intercalation compounds. The rudimentary cell consists of an anode, a cathode, an electrolyte and a separator, wherein lithium ions reversibly intercalate and de-intercalate into/from the anode and cathode materials on operation (discharge/recharge cycles). The materials consist of a host material with Li⁺ ions accessible to inter-atomic sites. Lithium ion intercalation/de-intercalation causes a change in the charge distribution inside the host material skeleton and an overall change in the material charge which, in turn, causes electron flow in the external circuit. The lithium is in an “almost atomic” state in a carbonaceous anode material, and it is in an “almost Li⁺” state inside the cathode material, being oxidized by a transition metal redox couple. Whereas lithium mobility in the carbon anode is sufficiently high, the development of cathode materials with substantial Li⁺ mobility turned out to be an issue of prime importance.

One of the most promising high voltage cathode materials for Li-ion electrochemical cells are spinel-type materials with a general formula of LiₓM_{y}Mn_{2-y}O₄ wherein M is typically Ni, Co, Fe, Cr and the likes. Among these materials, there are a substantial number of cathodes with the high de-lithiation potentials (over 5 V), whereas the de-lithiation potentials of the popular layered oxides are substantially lower; a high discharge potential is an advantage because the battery with higher voltage has higher energy density having the same charge capacity.

Typical cathodes are prepared using small particles of an active material in order to offer shorter Li⁺-diffusion pathways and shorter conductive electron pathways. The fine powdered (particles) cathode material suggests a high overall material surface area, though; this circumstance is associated with elevated rate of the spinel material dissolution in the course of discharge/recharge cycling in commonly employed Li-ion electrolytes. It is generally accepted that the dissolution mechanism involves the passage of the surface Mn⁺³ ions into the electrolyte during battery discharge/recharge cycles. This cathode material dissolution compromises the cathode electrical conductivity and leads to the battery capacity losses; as the result, the promising spinel-type materials suffer from an impractically short lifetime in terms of discharge/recharge cycle number.

Furthermore, while spinel-type material based lithium ion batteries typically have good performance at room temperature, these batteries suffer a gradual loss of delivered capacity with cycle number at elevated temperatures, referred to as capacity fade or the capacity fade rate. Researchers in the art have devoted substantial effort to reducing this loss in capacity.

The state of the art approach to address this challenge is by preventing the cathode material dissolution using surface coating of the cathode particles with protective layers. Such coating is supposed to act as a Mn⁺³ barrier, blocking the passage of the manganese ions into the electrolyte, thereby mitigating the cathode material dissolution. At the same time, such coating is required to allow easy Li⁺ ion diffusion pathways and therefore to maintain the desired battery power performance. Moreover, the coating should be stable by itself under the battery operation conditions, namely to sustain hydrofluoric acid attacks, because hydrofluoric acid, which is the byproduct of the electrolyte decomposition, is a very reactive/corrosive component of the LIB media.

The prior art provides different types of the cathode material coatings; most of which are based on metal oxides such as alumina. Such metal oxides may be used as Mn⁺³ barriers, however these oxides suffer from limited resistance against hydrofluoric acid attack, especially at elevated temperatures. In addition, most of the metal oxides, which have low Mn⁺³ permeability, also exhibit poor Li⁺ permeability [e.g., U.S. Pat. No. 9,012,096; Jung, E. et al., J. Electroceram., 2012, 29, p. 23-28; Wei He et al., RSC Advances, 2012, 2, p. 3423-3429; and Shi, S. J. et al., Electrochimica Acta, 2013, 108, p. 441-448].

Thin protection layers, which are based on metal oxides and were deposited by ALD technique, have demonstrated a good uniformity over all powder surfaces and fair Li+ permeability [e.g., Scott, I. D. et al., Nano Lett., 2011, 11, p. 414-418; Jung, Y. S. et al., J. Electrochem. Soc., 2010, 157, p. A75-A81; and Guan, D. et al., Nanoscale, 2011, 3, p. 1465-1469]. However, metal oxides are prone to hydrofluoric acid attack and promptly degrade with discharge/recharge cycling, while increasing the coating's thickness enhances the coating stability but compromises Li+-diffusivity.

It was demonstrated that metal fluorides are more adequate for the protective cathode coating, compared to metal oxides, since some metal fluorides combine low Mn⁺³ permeability with high Li⁺ permeability, and moreover, metal fluorides are impervious to hydrofluoric acid attacks [e.g., Sun, Y.-K. et al., J. Electrochem. Soc., 2007, 154, p. A168-A172; and Sun, Y.-K. et al., Adv. Mater., 2012, 24 p. 1192-1196].

Metal fluorides were employed for spinel cathode protective coating using “wet” chemical deposition processes [e.g., Kim, J.-H. et al., J Alloys and Compounds, 2012, 517:20-25; Xu, K. et al., Electrochimica Acta, 2012, 60:130-133; Lee, H. J. et al., Solid State Ionics, 2013, 230:86-91; Liu, X. et al., Electrochimica Acta, 2013, 109, pp. 52-58; Lu, C. et al., J. Power Sources, 2014, 267, pp. 682-691; and Lee, H. J. et al., Nanoscale Research Letters, 2012, 7(16)]. However, wet chemistry-based metal fluoride deposition processes afford non-uniform and/or porous coatings [Bernsmeier, D. et al., ACS Appl. Mater. Interfaces, 2014, 6:19559-19565], which lead to low protective features and/or low Li⁺ permeability. Although some battery lifetime improvements were reported, it has been shown that in some areas the protective film failed to prevent Mn⁺³ passage while another areas of the same coated sample exhibited too high resistance for Li⁺ permeability; evidently, such performance compromises cathode cycle life.

Thin films of magnesium fluoride (MgF₂) were used for many different optics applications. In particular, these films were found useful for ultraviolet anti-reflective and protective coatings, and in some applications where very thin films are needed, atomic layer deposition (ALD) has been found ideal [Pilvi, T et al., Chemistry Of Materials, 2008, 20(15), pp. 5023-5028]. Thin films of aluminum fluoride (AlF₃) were also grown on monolithic p-type boron-doped Si (100) wafers using trimethylaluminum (TMA) and hydrogen fluoride (HF) [Lee, Y. et al., J. Phys. Chem., 2015, 119:14185-14194].

Amorphous composite aluminum-tungsten-fluoride (AlWₓF_{y}) films were formed on laminates of LiCoO₂ by ALD using trimethylaluminum (TMA) and tungsten hexafluoride (WF₆) at 200° C. [Park, J. S. et al., Chem. Mater., 2015, 27:1917-1920].

Several recent studies used ALD technique for implementing oxide and nitride protective layers on LIB electrodes [Snyder, M. Q. et al., Thin Solid Films, 2006, 514:97-102; Snyder, M. Q. et al., J. Powder Sources, 2007, 165:379-385; Lipson, A. L. et al., Chem. Mater, 2014, 26:935-940; Zhang, X. et al., Adv. Energy Mater, 2013, 3:1299-1307; and Kim, J. W. et al., J Power Surfaces, 2014, 254;190-197]. In these studies the researchers have attempted to coat pre-casted electrodes, which resulted in single-sided coated electrode.

U.S. Pat. No. 9,005,816 is directed at method of reducing the overpotential of the Li-air battery, which is effected by depositing an inert layer comprising inter alia metal fluoride on the surface of a carbon cathode using ALD, and further depositing a layer of a metal or metal oxide catalyst over the inert layer.

Additional background art includes U.S. Pat. Nos. 5,147,738, 5,705,291, 5,759,720, 6,183,718, 6,468,695, 6,489,060, 6,489,060, 6,492,061, 6,558,844, 7,049,031, 7,108,944, 7,294,435, 8,007,941, 8,034,486, 8,535,832, 8,663,849, 8,741,483 and 8,835,049, and U.S. Patent Application No. 20140255798.

### SUMMARY OF THE INVENTION

Embodiments presented in the instant disclosure provide, inter alia, a general process for modifying particles of lithium-ion cathode materials by coating the particles with a uniform protective layer of a metal fluoride using the atomic layer deposition (ALD) technique. Metal fluorides are the materials of choice for protective cathode coatings, according to some embodiments of this disclosure, since these materials are stable under Li-ion battery (LIB) operation conditions, where hydrofluoric acid may be present. The presently disclosed methodology offers the optimal material selection for the cathode protection material employing the advantages of the ALD technique. The presently disclosed coating of powdered cathode materials using metal fluorides by ALD processes can extend the usability of a LIB by extending the number of discharge/recharge cycles.

According to some embodiments, the use of ALD to coat the irregular particulate (powderous) cathode material having a spinel-type structure (LiₓM_{y}Mn_{2-y}O₄; M=Ni, Co, Fe, Cr, etc.), with a layer of a metal fluoride, allows the controllable formation a uniform Mn³⁺ impermeable (barrier), Li⁺ permeable (substantially low Mn⁺³ permeability and substantially high Li⁺ permeability) and hydrofluoric-resistant layer which leaves essentially no “too thin” or bald spots and areas, and no “too thick” spots or areas on the surface of the cathode material.

According to an aspect of some embodiments of the present invention, there is provided a composition-of-matter that includes a particulate lithium intercalation material coated with a layer of a metal fluoride, wherein:

the layer is characterized by a uniform thickness over at least 75% of the surface of the particulate lithium intercalation material, and/or

the layer is characterized by a uniform thickness over a contiguous area of at least 50 nm² of the surface of the particulate lithium intercalation material; and

the uniform thickness is characterized by at least n atomic periods of the metal fluoride and a deviation of ±m atomic periods,
wherein n is an integer greater than 2 and m is 1 for n smaller than 5 or an integer that ranges from 1 to n/5 for n greater than 5; and/or
the uniform thickness is characterized by an average thickness of h nanometers and a relative standard deviation of ±k %,
wherein h is at least 0.2 and k is less than 20.

According to an aspect of some embodiments of the present invention, there is provided a method of reducing the charge/discharge capacity fade rate of a rechargeable lithium-ion battery having an electrode, the method includes coating a particulate lithium intercalation material with a layer of a metal fluoride to thereby form a metal fluoride coated particulate lithium intercalation material, and forming the electrode from the coated particulate lithium intercalation material, wherein:

the layer is characterized by a uniform thickness over at least 75% of a surface of the particulate lithium intercalation material, and/or

the layer is characterized by a uniform thickness over a contiguous area of at least 50 nm² of a surface of the particulate lithium intercalation material; and

the uniform thickness is characterized by at least n atomic periods of the metal fluoride and a deviation of ±m atomic periods,
wherein n is an integer greater than 2 and m is 1 for n smaller than 5 or an integer that ranges from 1 to n/5 for n greater than 5; and/or

the uniform thickness is characterized by an average thickness of h nanometers and a relative standard deviation of ±k %,
wherein h is at least 0.2 and k is less than 20.

According to an aspect of some embodiments of the present invention, there is provided a lithium intercalation electrode that includes a particulate lithium intercalation material coated with a layer of a metal fluoride, wherein:

the layer is characterized by a uniform thickness over at least 75% of a surface of the particulate lithium intercalation material, and/or

the layer is characterized by a uniform thickness over a contiguous area of at least 50 nm² of a surface of the particulate lithium intercalation material; and

the uniform thickness is characterized by at least n atomic periods of the metal fluoride and a deviation of ±m atomic periods,
wherein n is an integer greater than 2 and m is 1 for n smaller than 5 or an integer that ranges from 1 to n/5 for n greater than 5; and/or
the uniform thickness is characterized by an average thickness of h nanometers and a relative standard deviation of ±k %,
wherein h is at least 0.2 and k is less than 20.

According to an aspect of some embodiments of the present invention, there is provided a rechargeable lithium-ion battery that includes:

a cathode,

an anode,

a separator, and

an electrolyte that includes lithium ions,

wherein:

at least one of the cathode and/or the anode includes a particulate lithium intercalation material coated with a layer of a metal fluoride, wherein:

the layer is characterized by a uniform thickness over at least 75% of a surface of the particulate lithium intercalation material, and/or

the layer is characterized by a uniform thickness over a contiguous area of at least 50 nm² of a surface of the particulate lithium intercalation material; and

the uniform thickness is characterized by at least n atomic periods of the metal fluoride and a deviation of ±m atomic periods,
wherein n is an integer greater than 2 and m is 1 for n smaller than 5 or an integer that ranges from 1 to n/5 for n greater than 5; and/or

the uniform thickness is characterized by an average thickness of h nanometers and a relative standard deviation of ±k %,
wherein h is at least 0.2 and k is less than 20.

According to some of any of the embodiments of the invention, n≥5.

According to some of any of the embodiments of the invention, n≥10 and 1≤m≤n/10.

According to some of any of the embodiments of the invention, h is at least 0.2 nanometer.

According to some of any of the embodiments of the invention, h is at least 0.5 nanometer.

According to some of any of the embodiments of the invention, h is at least 1 nanometer.

According to some of any of the embodiments of the invention, h is at least 2 nanometer.

According to some of any of the embodiments of the invention, h is at least 3 nanometer.

According to some of any of the embodiments of the invention, h is at least 4 nanometer.

According to some of any of the embodiments of the invention, h is at least 5 nanometer.

According to some of any of the embodiments of the invention, k≤10.

According to some of any of the embodiments of the invention, the metal is selected from the group consisting of an alkali metal, an alkali earth metal, a lanthanide and any combination thereof.

According to some of any of the embodiments of the invention, the particulate lithium intercalation material is a lithium intercalation cathode material and/or a lithium intercalation anode material.

According to some of any of the embodiments of the invention, the lithium intercalation cathode material is selected from the group consisting of a layered dichalcogenide, a trichalcogenide, a layered oxide, a spinel-type material and an olivine-type material.

According to some of any of the embodiments of the invention, the spinel-type material is lithium manganese oxide and/or lithium nickel manganese cobalt oxide.

According to some of any of the embodiments of the invention, the olivine-type material is lithium iron phosphate.

According to some of any of the embodiments of the invention, the lithium intercalation cathode material is selected from the group consisting of LiMn_{1.5}Ni_{0.5}O₄, LiNi_{1/3}Mn_{1/3}Co_{1/4}O₂, LiMnO₂, LiMn₂O₄ and Li[Li_{0.1305}Ni_{0.3043}Mn_{0.5652}]O₂.

According to some of any of the embodiments of the invention, the lithium intercalation anode material is selected from the group consisting of amorphous carbon, graphite, graphene, Buckminsterfullerenes, carbon nanotubes, carbon nanobuds, titanium oxide, vanadium oxide, lithium titanate, molybdenum oxide, silicon, a silicon alloy, tin and a tin alloy.

According to some of any of the embodiments of the invention, the average particle size of the particulate lithium intercalation material ranges from 1 nanometers to 600 micrometers.

According to some of any of the embodiments of the invention, the layer is formed by atomic layer deposition (ALD) process.

According to some of any of the embodiments of the invention, the ALD process includes:

i) exposing particles of a lithium intercalation material to a source of the metal while moving the particles relative to themselves;

ii) exposing the particles to a source of fluoride while moving the particles relative to themselves; and

iii) repeating Step (i) and Step (ii) for n cycles,

wherein n≥2.

According to some of any of the embodiments of the invention, the ALD process further includes exposing the particles to water and/or ozone after each of Step (i) and Step (ii).

According to some of any of the embodiments of the invention, the ALD process further includes heating said particles to an optimizing temperature.

According to an aspect of some embodiments of the present invention, there is provided a process of coating a particulate lithium intercalation material with a layer of a metal fluoride, the process includes:

i) exposing particles of the lithium intercalation material to a source of the metal while moving the particles relative to themselves;

ii) exposing the particles to a source of fluoride while moving the particles relative to themselves; and

iii) repeating Step i and Step ii for n cycles,

wherein n≥2.

According to some of any of the embodiments of the invention, the layer of the metal fluoride is characterized by a number of atomic periods of the metal fluoride, and n corresponds to the number of the atomic periods.

According to some of any of the embodiments of the invention, the process further includes exposing the particles to water and/or ozone after each of Step (i) and Step (ii).

According to some of any of the embodiments of the invention, the process further includes heating said particles to an optimizing temperature.

According to some of any of the embodiments of the invention, the source of the metal is selected from the group consisting of bis-ethyl-cyclopentadienyl-magnesium, bis(pentamethylcyclopentadienyl)magnesium, bis(6,6,7,7,8,8,8, heptafluoro-2,2-dimethyl-3,5-octanedionate)calcium, bis(cyclopentadienyl)zirconium(IV)dihydride, dimethylbis(pentamethylcyclopentadienyl)zirconium(IV), bis(pentafluorophenyl)zinc, diethylzinc, triisobutylaluminum and tris(2,2,6,6-tetramethyl-3,5-heptanedionate)aluminum.

According to some of any of the embodiments of the invention, the source of fluoride is selected from the group consisting of hexafluoroacetylacetonate, TaF₅ and TiF₄.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a bright field TEM electron-micrographs of a cross-sectional view of a LiMn_{1.5}Ni_{0.5}O₄ particle coated with a uniform layer of MgF₂ comprising 12 atomic periods using an ALD process, demonstrating the uniformity and evenness of the coating MgF₂ layer having a relative standard deviation of the coat's thickness in nanometer is less than 10% and being devoid of humps, gaps and holes;

FIG. 2 presents a comparative plot of the charge/discharge capacity of a cathode made with particles of LiMn_{1.5}Ni_{0.5}O₄ as a function of the number of charge/discharge cycles using an electrolyte that includes 1 M LiPF₆ in ethylene carbonate/dimethyl carbonate (1:1 volume ratio) and a Li-metal counter electrode at the room temperature, wherein Curve 1 represents the charge capacity of the cathode made with pristine (uncoated) particles, Curve 2 represents the discharge capacity of the cathode made with pristine particles, Curve 3 represents the charge capacity of the cathode made with LiMn_{1.5}Ni_{0.5}O₄ particles coated with 12 atomic periods of MgF₂ using ALD, according to some embodiments of the present invention, and Curve 4 represents the discharge capacity of the same cathode made with coated particles, and showing that the cathode made with uncoated particles exhibits substantial capacity fade (15% during the first 45 cycles), while the cathode made with coated particles exhibit insignificant capacity fade; and

FIG. 3 presents a plot of charge/discharge capacity of a cathode made with LiMn_{1.5}Ni_{0.5}O₄ particles as a function of the number of charge/discharge cycles at 45° C., wherein Curve 1 represents the charge capacity of a cathode made with pristine (uncoated) particles, Curve 2 represents the discharge capacity of the cathode made with pristine particles, Curve 3 represents the charge capacity of a cathode made with particles coated with 6 atomic periods of MgF₂ using ALD, according to some embodiments of the present invention, Curve 4 represents the discharge capacity of the same coated cathode material, Curve 5 represents the charge capacity of the cathode material coated with 12 MgF₂ by ALD according to some embodiments of the present invention, and Curve 6 represents the discharge capacity of the same cathode made with coated particles, showing that the protective coating is more pronounced at elevated temperature compared to that demonstrated at room temperature (FIG. 2), as the uncoated cathode material exhibits 84% fade of the initial capacity after the first 15 cycles, while the coated material exhibits only 22% of capacity fade;

FIGS. 4A-J present HRSEM images of MNS particles coated with MgF₂ (1% by weight) using a wet deposition coating process, wherein FIGS. 4A-B show amorphous and non-uniform MgF₂ coating, FIGS. 4C-D show amorphous and non-uniform MgF₂ coating after heat treatment at 400° C., and FIGS. 4E-J show grains and humps of MgF₂ on the surface of the coated particle;

FIGS. 5A-F present bright field TEM electron-micrographs of cross-sectional views of Mn-rich NMC powder particles coated with MgF₂ by ALD process, wherein FIGS. 5A-B show a uniform thickness of about 1.2 nm after 2 ALD cycles, FIGS. 5C-D show s uniform thickness of about 1.8 nm after 4 ALD cycles, and FIGS. 5E-F show a uniform thickness of about 3.4 nm after 6 ALD cycles;

FIG. 6 presents a comparative plot of the charge/discharge capacity as a function of charge/discharge cycles as measured in full cells comprising the particles presented in FIGS. 4A-F normalized against the performance of uncoated particles, showing improved capacity stability of the coated particles compared to the reference;

FIGS. 7A-C present bright field TEM electron-micrographs of cross-sectional views of Mn-rich NMC powder particles coated with MgF₂, showing the uniform thickness of the MgF₂ layer after 2 ALD coating cycles (FIG. 7A), after 3 ALD coating cycles (FIG. 7B), after 6 ALD coating cycles (FIG. 7C), and

FIG. 7D is a plot of thickness as a function of ALD cycles summarizing the results presented in FIG. 7A-C, showing about 0.7 nm increase in thickness per each ALD cycle;

FIGS. 8A-F present bright field TEM electron-micrographs of cross-sectional views of Ni-rich NMC powder particles coated with MgF₂ by ALD process effected at various temperatures, wherein FIGS. 8A-B show a uniform thickness afforded after 2 ALD cycles at 350° C., FIGS. 8C-D show a uniform thickness afforded after 4 ALD cycles at 275° C., and FIGS. 8E-F show a uniform thickness afforded after 6 ALD cycles at 275° C.;

FIGS. 9A-B present comparative plots of charge/discharge capacity as a function of charge/discharge cycles, as measured in cells produced with the coated particles presented in FIGS. 8A-F;

FIGS. 10A-D presents HRSEM images of MNS particles coated with MgF₂ by 6 ALD cycles, taken after the particles were kept in the electrolyte solution for one month at room temperature (FIGS. 10A-B) and for one week at 45° C. followed by 3 weeks at room temperature (FIGS. 10C-D); and

FIGS. 11A-B presents bright field TEM electron-micrographs of cross-sectional views of NMC powder particles coated with AlF₃ by ALD process, wherein FIG. 10A shows a uniform thickness of about 1.5 nm after 6 ALD cycles, and FIG. 10B shows uniform thickness of about 2 nm after 10 ALD cycles.

### DESCRIPTION OF SPECIFIC EMBODIMENTS OF THE INVENTION

The present invention, in some embodiments thereof, relates to electrochemistry, and more particularly, but not exclusively, to a modified particulate lithium intercalation electrode material and a method of reducing a capacity fade rate during discharge/recharge cycling of a lithium-ion rechargeable battery.

The principles and operation of the present invention may be better understood with reference to the figures and accompanying descriptions.

Before explaining at least one embodiment of the invention in detail, it is to be understood that the invention is not necessarily limited in its application to the details set forth in the following description or exemplified by the Examples. The invention is capable of other embodiments or of being practiced or carried out in various ways.

As discussed hereinabove, lithium ion intercalation-based electrochemical cells using spinel-type cathodes are prone to loss of efficacy due to loss of manganese from the cathode material, namely dissolution of Mn⁺³ ions from the spinel-type cathode material into the electrolyte during battery discharge/recharge cycles. One promising approach involves coating the cathode material with a “Mn⁺³ barrier”, however, the presently known barriers provide a limited solution to the problem due to insufficient stability, and lack of uniformity which leads to inconsistent Li⁺ permeability.

While metal fluoride coatings have been known to provide some protection to pre-assembled lithium intercalation cathodes, these approaches failed to provide a significant improvement in terms of charge/discharge capacity fade rate reduction.

While conceiving the present invention, the present inventors have speculated that deficiency of the uniformity of the metal fluoride coating over the cathode material is the reason for the observed fade rate of the coated electrodes. In an attempt to improve the performance of lithium intercalation electrodes, the present inventors have surprisingly found that if the electrode is made from particulate lithium intercalation material, which has been coated uniformly by a metal fluoride layer, prior to constructing the electrode, the LIB based thereon exhibits a remarkable reduction of the fade rate in the charge/discharge capacity of the battery.

Fading of the charge capacity during charge/discharge cycling is a known problem in the art of LIB. In general the charge/discharge capacity fade rate during cycling (referred to herein for short as “fade rate”) depends on the charge/discharge conditions, such as temperature and charge/discharge rate, and also on various manufacturing parameters, such as electrode preparation, electrolyte composition, anode/cathode binder material and the likes. The fade rate also depends on the charge/discharge protocol and the deepness of the charge/discharge. It is noted that fade rate is typically not a linear function of the numbers of charge/discharge cycles. Typically, LiCoO₂ cathode material exhibits about 5% fade rate per 300 cycles at 1C rate or less. It is noted that a “1 C rate” means, as known in the art, that the discharge current will entirely discharge the battery in 1 hour. For example, for a battery with a capacity of 100 Amp-hours, this equates to a discharge current of 100 Amps; a 5 C rate for the same battery would be 500 Amps; and a C/2 rate would be 50 Amps. As demonstrated in the Examples section that follows below, the typical fade rate of 5% per 300 cycles at 1 C rate is higher (less desirable) than the fade rate which is achieved by using the methodology provided herein.

As demonstrated in the Examples section below, the fade rate of a cathode made from a magnesium fluoride coated particulate lithium intercalation material, according to some embodiments of the present invention, can be reduced by more than 15% at room temperature and more that 60% at 45° C., compared to the fade rate exhibited by uncoated particulate lithium intercalation material. The provisions of the present invention can be applied for both anodes and cathodes, thereby improving substantially the lifespan of both electrode materials to a similar extent.

Thus, according to an aspect of some embodiments of the present invention, there is provided a particulate lithium intercalation material coated with a layer of a metal fluoride, wherein the metal fluoride layer is characterized by a substantially uniform thickness over the surface of each particle of the lithium intercalation material.

As used herein the term “particulate” refers to a substance that is composed of separate particles, wherein the term “particle” is used herein to describe an individual and relatively small object to which can be ascribed several physical or chemical properties such as chemical composition, shape, surface (and surface area), volume and mass.

It is noted herein that the use of particulate lithium intercalation material, in the context of some embodiments of the present invention, is advantageous due to the extended surface area thereof, compared to a monolithic object made from the same lithium intercalation material, and compared to an object pre-formed from particulate lithium intercalation material.

According to some embodiments of the invention, the particle shape of the particulate lithium intercalation material is a spheroid, a box or any symmetric or irregular polyhedron.

According to some embodiments of the invention, the average particle size of the particulate lithium intercalation material ranges from 1 nanometers to 600 micrometers in diameter, and larger. The particulate lithium intercalation material may comprise agglomerated particles, the coating of which with a metal fluoride, according to embodiments of the present invention, is also contemplated within the scope of some embodiments thereof.

According to some embodiments of the invention, the surface area of an average individual particle of the particulate lithium intercalation material ranges from 80 nm² (square nanometer) to 8,000 μm² (square micrometer).

As discussed hereinabove, the longevity of a LIB in terms of recharge/charge capacity fate rate, relates to waning lithium intercalation properties of the electrodes, which is related to leakage of certain elements from the lithium intercalation material, such as manganese and nickel. This lithium intercalation material degradation is associated with electrolyte effects; thus, while some techniques have been used to protect the lithium intercalation material from the electrolyte effects by coating, these coating techniques either left holes and gaps in the protecting coating, or formed lithium-ion impervious surfaces on the lithium intercalation material. In sharp contrast, the metal fluoride layer that coats the particulate lithium intercalation material, according to some embodiments of the present invention, covers substantially the entire lithium intercalation material particle, leaving no holes or gaps in the coating layer, and no lithium intercalation material particle surface that can be exposed to the electrolyte. Such uniformity of the metal fluoride later cannot be achieved if parts of the particle surface are obscured during the coating process, but become accessible to the electrolyte when used to form a lithium intercalation electrode, as happens, for example, when the particles are bonded together with a binder material while being coated with a protection later. As known in the art, binder material, particularly of the type used to bond particulate lithium intercalation material in the making of a lithium intercalation electrode, is selected so as to allow access of electrolyte species and solutes to the lithium intercalation material that comprises the electrode; however, the presence of binder substance on the surface of the lithium intercalation material particles would impede the formation of a metal fluoride layer thereon. Hence, forming a metal fluoride layer on the surface of particulate lithium intercalation material which is already bonded together with a binder would leave holes and gaps in the metal fluoride layer at least in the areas where binder substance is present on the surface of the particles. In addition, it is further assumed that an attempt to coat the lithium intercalation materials by ALD, after it has been bound with a binder and used to construct an electrode, would fail since the binder would disintegrate under ALD conditions, and the electrode would no longer function as intended.

In some embodiments of the present invention, the term “surface” in the context of the surface of a particle of a lithium intercalation material, refers to the gas-accessible surface of the particle, wherein the term “gas” refers to any gaseous substance or vapors of a substance (mixed with a carrier gas or not), and the term “accessible” refers to the ability of molecules in the gas or vapors to reach the surface.

It is noted that the binder-restricted temperature also limits the use of the optional thermal treatment of the metal fluoride layer, which requires heating the coated particles to higher temperatures. As discussed hereinbelow, the thermal treatment of the coated particles is effected in order to optimize the layer's morphology from amorphous to more crystalline, rendering the protective metal fluoride layer more stable.

According to some embodiments of the invention, the layer of metal fluoride covering the surface of particulate lithium intercalation material is substantially devoid of holes and gaps, which are accessible to an electrolyte when the particulate lithium intercalation material is in contact with the electrolyte. In some embodiments, the entire surface of the metal fluoride coated lithium intercalation material particles presented herein is coated with a uniform layer of metal fluoride such that essentially no uncoated parts of the surface of the particles are accessible directly to the electrolyte. For example, when an agglomerate of lithium intercalation material particles is coated with a metal fluoride layer, according to embodiments of the present invention, the agglomerate is treated as an individual particle, having its entire gas-accessible surface evenly coated with the metal fluoride layer, leaving to hole and gaps that can be accessible directly to an electrolyte. When such uniformly coated agglomerates are used to form a lithium intercalation electrode, the lithium intercalation material would not be exposed to the electrolyte. In the context of embodiments of the present invention, a gas-accessible surface of an object is any area on the surface of the object which can be reached by a gas molecule or a molecule of a vaporized substance carried by a gas.

In the context of some embodiments of the present invention, the term “surface” refers to a gas-accessible surface of an object, wherein the object can be a particle or an agglomerate of particles. In it noted that in the context of embodiments of the present invention, a gas-accessible surface may be accessible to electrolyte species when immersed in an electrolyte. This distinction is relevant for particles which have been coated by a gas-phase coating technique, such as ALD, and thereafter exposed to an electrolyte; such particles have no part of their surface directly exposed to the electrolyte. The distinction is also relevant for particles which have been bonded by a binder substance prior to the gas-phase coating process; such particles have parts of their surface that are exposed to electrolyte species, particularly in those areas contacted by the binder substance that hinders gas accessibility, since the binder substance is selected for permeability of electrolyte species therethrough.

According to some embodiments of the invention, the coating of the lithium intercalation material particles is afforded by atomic layer deposition, as this methodology, which contributes to the uniformity of the metal fluoride layer. Since ALD is used to apply a single atomic layer of the coating substance in each deposition cycle, referred to herein as an “atomic period”, the metal fluoride layer deposited on the surface of the lithium intercalation material particles is characterized by a thickness that ranges from 2 to 50 atomic periods of the metal fluoride.

As used herein, the term “atomic period” refers to the result of a single atomic layer deposition cycle, which is defined as a complete cycle wherein the substrate has been exposed sequentially to all precursor materials. A single atomic period can also be characterized by a periodic tenuity, namely the thickness of a single atomic period.

Unlike other methods of wet coating, the first atomic periods afforded by ALD (typically 3-5 atomic periods) may be epitaxial, i.e. their lattice is strongly influenced by the lattice of the substrate, rather that exhibit the structure of the bulk metal fluoride. Hence, according to some embodiments of the present invention, at least 5 atomic periods of the metal fluoride layer on the surface of the lithium intercalation material particles presented herein, are characterized by a lattice structure which is substantially the lattice of the lithium intercalation material.

The ability of the metal fluoride coated particulate lithium intercalation material, presented herein, to significantly reduce the charge/discharge capacity fade rate, is attributed inter alia, to the uniformity of the metal fluoride coating.

The requirement for uniformity of the metal fluoride layer, according to some embodiments of the present invention, is kept for at least some part of the surface of the particle. This part of the surface can be expressed in percentage of the entire surface of the particle, and denoted by “S %”. For non-limiting example, the thickness of the layer of the metal fluoride is uniform over at least 25% of the total surface of the particle, or at least 30% (S≥30), or at least 35% (S≥35), or at least 40% (S≥40), or at least 45% (S≥45), or at least 50% (S≥50), or at least 55% (S≥55), or at least 60% (S≥60), or at least 65% (S≥65), or at least 70% (S≥70), or at least 75% (S≥75), or at least 80% (S≥80), or at least 85% (S≥85), or at least 90% (S≥90), or at least 95% (S≥95) of the total surface of the particle.

According to some embodiments of the present invention, the metal fluoride layer is characterized by a uniform thickness over at least 75% (S≥75) of the surface of each particle in the particulate lithium intercalation material.

Additionally or alternatively, the requirement for uniformity of the metal fluoride layer, according to some embodiments of the present invention, is kept for minimal surface area of the particle. For non-limiting example, the thickness of the layer of the metal fluoride is uniform over at least 10 nm², at least 20 nm², at least 30 nm², at least 40 nm², at least 50 nm², at least 60 nm², at least 70 nm², at least 90 nm², at least 100 nm², at least 150 nm², at least 200 nm², at least 250 nm², at least 300 nm², at least 350 nm², at least 400 nm², at least 450 nm², at least 500 nm², at least 1000 nm², at least 1500 nm², at least 2000 nm², at least 2500 nm², at least 3000 nm², at least 3500 nm², at least 4000 nm², at least 4500 nm², at least 5000 nm², at least 6000 nm², at least 7000 nm² or at least 8000 nm² of the surface area of the particle.

Additionally or alternatively, the metal fluoride layer is characterized by a uniform thickness over a contiguous (uninterrupted, continuous, unbroken, successive) area of at least 50 nm² of the surface of each particle in the particulate lithium intercalation material.

According to some embodiments of the present invention, the uniformity of the thickness of the layer of the metal fluoride over the surface of the particle, can be expressed by a maximal deviation of the number of atomic periods over the surface of the particle. Hence, according to some embodiments of the present invention, the uniform thickness of the metal fluoride layer is characterized by at least n atomic periods of the metal fluoride and a deviation of ±m atomic periods, wherein both n and m are integers, and n≥2 and m=1 for n≤5, or 1≤m≤n/5 for n≥5.

According to some embodiments of the present invention, n≥3, n≥4, n≥5, n≥6, n≥7, n≥8, n≥9, n≥10, n≥11, n≥12, n≥13, n≥14, n≥15, n≥16, n≥17, n≥18, n≥19, n≥20, n≥21, n≥22, n≥23, n≥24, n≥25, n≥26, n≥27, n≥28, n≥29 or n≥30.

According to some embodiments of the present invention, n≥10 and 1≤m≤n/10.

In some embodiments, the maximal deviation of the thickness over at least 75% of the surface of the article is less than 2 atomic periods. In other words, for a layer of 20 atomic periods, the layer is regarded uniform if its thickness ranges from 18 to 22 atomic periods. In some embodiments, the thickness uniformity is characterized by a maximal deviation of 2, 3, 4, 5, 6, 7, 8, 9 or 10 atomic periods.

According to some embodiments of the present invention, the uniformity of the thickness of the layer of the metal fluoride over the surface of the particle can be expressed in terms of physical thickness variations, as can be measured by any physical, electronic, spectral and/or optical method. The absolute thickness of the metal fluoride layer depends on the type of metal fluoride and the number of atomic periods which is applied on the surface of the particle. Hence, the uniform thickness of the metal fluoride layer is characterized by an average thickness of h nanometers and a relative standard deviation of k %, wherein h≥0.2 (h is at least 0.2 nanometer) and k≤20 (k is equal or less than 20%).

According to some embodiments, 0.2≤h≤100, or in other words, the average thickness of the layer ranges from 1 nm to 100 nm.

According to some embodiments h≥0.2, h≥0.5, h≥1, h≥2, h≥3, h≥4, h≥5, h≥6, h≥7, h≥8, h≥9, h≥10, h≥11, h≥12, h≥13, h≥14, h≥15, h≥16, h≥17, h≥18, h≥19, h≥20, h≥30, h≥40, h≥50, h≥60, h≥70, h≥80, h≥90 or h≥100.

According to some embodiments, k≤20, k≤19, k≤18, k≤17, k≤16, k≤15, k≤14, k≤13, k≤12, k≤11, k≤10, k≤9, k≤8, k≤7, k≤6 or k≤5.

While the entire surface of the particle may be covered with a layer of metal fluoride, the requirement for uniformity may be fulfilled for at least a certain part of the surface (see, S % hereinabove). For non-limiting example, in some embodiments, the uniformity of the metal fluoride layer is determined in terms relative standard deviation of thickness (k %) over a certain percentage of the surface of each particle in the particulate lithium intercalation material. In some embodiments, k≤40 for S≥95, k≤35 for S≥90, k≤30 for S≥85, k≤25 for S≥80, k≤20 for S≥75, k≤15 for S≥70, k≤10 for S≥65 or k≤5 for S≥60.

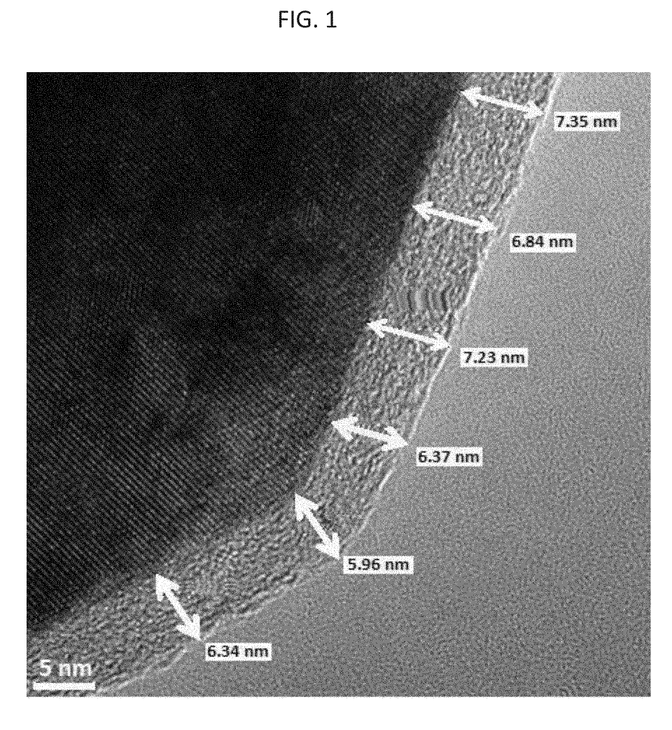

According to some embodiments of the present invention, the relative standard deviation (RSD % or k) of the thickness of the layer over at least 75% (S≥75) of said surface is less than 40% (k≤40 for S≥75), less than 30% (k≤30 for S≥75), less than 25% (k≤25 for S≥75), less than 20% (k≤20 for S≥75), less than 15% (k≤15 for S≥75), or less than 10% (k≤10 for S≥75). As can be seen in FIG. 1, the relative standard deviation of the coat's thickness, as measured in nanometers, is about 8.2% (k≈8.2).

In some embodiments, k≤40 for S≥80, k≤35 for S≥80, k≤30 for S≥80, k≤25 for S≥80, k≤20 for S≥80, k≤15 for S≥80, k≤10 for S≥80or k≤5 for S≥80.

In some embodiments, k≤40 for S≥85, k≤35 for S≥85, k≤30 for S≥85, k≤25 for S≥85, k≤20 for S≥85, k≤15 for S≥85, k≤10 for S≥85or k≤5 for S≥85.

In some embodiments, k≤40 for S≥90, k≤35 for S≥90, k≤30 for S≥90, k≤25 for S≥90, k≤20 for S≥90, k≤15 for S≥90, k≤10 for S≥90or k≤5 for S≥90.

In some embodiments, k≤40 for S≥95, k≤35 for S≥95, k≤30 for S≥95, k≤25 for S≥95, k≤20 for S≥95, k≤15 for S≥95, k≤10 for S≥95or k≤5 for S≥95.

In some embodiments, the metal fluoride is selected such that a layer thereof deposited by ALD is Li⁺-permeable (allows lithium ions to pass therethrough) while being impermeable with respect to the electrode metal ions (e.g., Mn⁺³).

In the context of some embodiments of the present invention, the term “metal fluoride” refers to a family of chemical compounds, within which fluorine forms polar covalent bonds with one or more metal atoms. In some embodiments, the fluorine forms polar covalent bonds rather than ionic bonds with the metal atom. In some embodiments, the metal in the metal fluoride is in an oxidation state of +2 or higher. In some embodiments, the metal in the metal fluoride is other than an alkali metal.

According to some embodiments of the present invention, the metal used for the metal fluoride layer can be any one of a variety of metals, including transition metals, noble metals, post-transition metals, base metals, poor metals, alkaline earth metals, lanthanides, actinides, and any combination thereof.

In the context of embodiments of the present invention, the term “alkali metal” refers to metals such as lithium (Li), sodium (Na), potassium (K), rubidium (Rb), cesium (Cs) and francium (Fr).

The term “alkali earth metal” refers to metals such as beryllium (Be), magnesium (Mg), calcium (Ca), strontium (Sr), barium (B a) and radium (Ra).

In the context of embodiments of the present invention, the term “lanthanide” encompasses lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu).

In the context of embodiments of the present invention, the term “actinide” encompasses actinium (Ac), thorium (Th), protactinium (PA), uranium (U), neptunium (Np), plutonium (Pu), americium (Am), curium (Cm), berkelium Bk), californium (Cf), einsteinium (Es), fermium (Fm), mendelevium (Md), nobelium (No) and lawrencium (Lr).

In the context of some embodiments of the present invention, the term “transition metal” encompasses zinc, molybdenum, cadmium, scandium, titanium, vanadium, chromium, manganese, iron, cobalt, nickel, copper, yttrium, zirconium, niobium, technetium, ruthenium, rhodium, palladium, silver, hafnium, tantalum, tungsten, rhenium, osmium, iridium, platinum, gold, mercury, rutherfordium, dubnium, seaborgium, bohrium, hassium and copernicium.

In the context of embodiments of the present invention, the term “noble metal” encompasses ruthenium, rhodium, palladium, silver, osmium, iridium, platinum, gold, mercury, rhenium and copper.

In the context of embodiments of the present invention, the term “post-transition metal” encompasses aluminum, gallium, indium, tin, thallium, lead, bismuth and polonium.

In the context of embodiments of the present invention, the term “base metal” encompasses iron, nickel, lead, zinc and copper.

In the context of embodiments of the present invention, the term “poor metal” encompasses aluminum, gallium, indium, thallium, tin, lead, bismuth, polonium, ununtrium, flerovium, ununpentium and livermorium.

In some embodiments, the metal fluoride layer, as described herein, comprises alkaline and alkaline earth metals, lanthanides, actinides, and any combination thereof.

In some embodiments, the metal fluoride layer, as described herein, comprises magnesium, aluminum, calcium, tungsten, molybdenum, zinc, niobium, hafnium, tantalum, tungsten, zirconium, titanium, yttrium, chromium, vanadium, lead and the like, and any combination thereof. For non-limiting example, the metal fluoride is magnesium fluoride (MgF₂), aluminum fluoride (AlF₃), calcium fluoride (CaF₂), ZnF₂, ZrF₄, MoF₂, MoF₅, MoF₆, WF₃, WF₄, WF₅ and WF₆.

In some embodiments, the metal fluoride layer comprises more than one type of metal fluoride, namely the layer comprises atomic periods having different metals per an atomic period. For example, the metal fluoride layer can include, according to some embodiments, a first atomic period having a first metal, and a second atomic period having a second metal. The metal fluoride layer can include a third, a fourth and a fifth metals, and more. The metal fluoride layer can include alternating atomic periods, each characterized by a different metal, or a series of atomic periods having the same metal, followed by a series of atomic periods having a different metal, and so on.

As stated hereinabove, each atomic period is characterized by periodic tenuity, which corresponds to the type of metal fluoride and the lattice thereof. For example, a MgF₂ atomic period is characterized by a periodic tenuity of about 5.8 Å (0.58 nm), and an AlF₃ atomic period is characterized by a periodic tenuity of about 2 Å (0.2 nm), as corroborated by the results presented in the Examples section that follows below.

According to some embodiments of the present invention, lithium intercalation materials include, without limitation, layered dichalcogenides, trichalcogenides, layered oxides, spinel-type materials, lithium-rich metal oxides, graphite and olivine-type materials.

It is noted that some of the lithium intercalation materials which are contemplated in some embodiments of the present invention are spinel-type materials. The term “spinel”, as used herein, refers to members of a class of minerals having the general formula A₂+B₃+2O₂₋₄, which solidifies in the cubic (isometric) crystal system, with the oxide anions arranged in a cubic close-packed lattice and the cations A and B occupying some or all of the octahedral and tetrahedral sites in the lattice. Although the charges of A and B in the prototypical spinel structure are +2 and +3, respectively, other combinations incorporating divalent, trivalent, or tetravalent cations, including magnesium, zinc, iron, manganese, aluminum, chromium, titanium, and silicon, are also contemplated. The anion is typically oxygen; when other chalcogenides constitute the anion sub-lattice the structure is referred to as a thiospinel. A and B can also be the same metal with different valences, as is the exemplary magnetite, Fe₃O₄ (as Fe₂+Fe₃+2O₂₋₄).

In the context of some embodiments of the present invention, a lithium intercalation material useful in the making of a lithium intercalation cathode material is a lithium-rich metal oxide which include oxides with layered structure (e.g., LiCoO₂, LiNi_{y}Co_{1-y}O₂, LiNi_{y}Mn_{y}Co_{1-2y}O₂ and alike), oxides with spinel structure (e.g., LiMn₂O₄, LiNi_{0.5}Mn_{1.5}O₄, LiMn_{2-y}Cr_{y}O₄ and alike), and oxides with olivine structure (e.g., LiFePO₄, LiFe_{1-y}Mn_{y}PO₄ and alike). Other non-limiting examples of lithium intercalation materials include, without limitation, LiNiMnCoO₂, Li_{1′x}Mn₂₋ₓO₄, Li₁₊ₓMn_{1-x-y}Al_{y}—O_{4-z}F_{z}, LiMn_{1-y}Co_{y}O₂, LiNi_{1-y}Mn_{y}O₂, LiNi_{1-y-z}Mn_{y}Co_{z}O₂, LiNi_{y}Mn_{y}Co_{1-2y}O₂, Li₁₊ₓ(Ni_{0.5}Mn_{0.5})₁₋ₓO₂, LiNi_{1-y}Mg_{y}O₂, LiNi_{1-y}Co_{y}O₂, LiNi_{1-y-z}Co_{y}Al_{z}O₂, LiNiCoAlO₂, LiMn_{1.5}Ni_{0.5}O₄, LiNi_{1/4}Mn_{1/3}Co_{1/3}O₂, LiMnO₂, LiMn₂O₄, Li[Li_{0.1305}Ni_{0.3043}Mn_{0.5652}]O₂, LiNiO₂, LiCoO₂ and LiNi_{0.8}Co_{0.15}Al_{0.05}O₂.

As known in the art and discussed hereinabove, lithium intercalation cathode materials that include manganese typically suffer from loss of Mn³⁺ into the electrolyte, causing degraded battery performance and charge capacity fade. In the context of embodiments of the present invention, the lithium intercalation cathode materials include manganese (e.g., LiMn_{1.5}Ni_{0.5}O₄). It is noted that the example of lithium intercalation cathode materials that include manganese is given as an exemplary model of cathode material deterioration, and should not be seen as limiting the invention to this type of embodiments. The invention is contemplated for a broader scope of cathode materials that do not include manganese, wherein coating the particles of the cathode material with a metal fluoride by ALD process is beneficial. For a non-limiting example, cathode material comprising lithium cobalt oxide can be beneficially coated by a metal fluoride using an ALD process.

According to some embodiments, the particulate lithium intercalation material can be used to construct a lithium intercalation cathode or to construct a lithium intercalation anode. According to some embodiments, particulate lithium intercalation materials characterized by highly positive intercalation potentials can be used to construct cathodes and particulate lithium intercalation materials with small positive intercalation potentials can be used to construct anodes.

According to some embodiments of the invention, the lithium intercalation cathode material is selected from the group consisting of a layered dichalcogenide, a layered trichalcogenide, a layered oxide, a spinel-type material and an olivine-type material.

According to some embodiments of the invention, the spinel-type material is lithium manganese oxide and/or lithium nickel manganese cobalt oxide.

According to some embodiments of the invention, the olivine-type material is lithium iron phosphate.

According to some embodiments of the invention, the lithium intercalation cathode material is selected from the group consisting of LiMn_{1.5}Ni_{0.5}O₄, LiNi_{1/3}Mn_{1/3}Co_{1/3}O₂, LiMnO₂, LiMn₂O₄ and Li[Li_{0.1305}Ni_{0.3043}Mn_{0.5652}]O₂.

In the context of some embodiments of the present invention, a lithium intercalation material coated with a uniform layer of a metal fluoride is useful in the making of a lithium intercalation anode. According to some embodiments of the invention, lithium intercalation anode material include, without limitation, carbon-based materials, amorphous carbon and various carbon allotropes (e. g., graphite, graphene, Buckminsterfullerenes, carbon nanotubes, carbon nanobuds and alike), crystalline and amorphous silicon-based anode materials, tin and tin alloy-based anode materials and various binary and ternary oxide materials such as lithium titanate (Li₄Ti₅O₁₂) and lithium molybdate, and various molybdenum oxides and combinations thereof (such as MoO₂ and MoO₃). More non-limiting examples of anode materials may be found in Reddy, M. V. et al., Chem. Rev., 2013, 113(7):5364-5457.

The process of coating particulate lithium intercalation material with a uniform layer of metal fluoride, deposited by ALD, as described herein, can be effected, according to some embodiments of the present invention, by:

i) exposing particles of a lithium intercalation material to a source (precursor) of the metal while moving the particles relative to themselves;

ii) exposing the particles to a source (precursor) of fluoride while moving the particles relative to themselves; and

iii) repeating Step i and Step ii for n cycles, wherein n is an integer ranging from 2 to 50 and representing the number of atomic periods of the metal fluoride deposited on the surface of the particles.

The ALD process, according to some embodiments of the present invention, is designed to achieve a uniform layer of the metal fluoride over the surface of particles, from at least 25% thereof and up to at least 95% thereof, wherein this uniform and extensive coverage is afforded by exposing the particles to the various precursors of the metal and the fluoride while moving the particles with respect to themselves, namely by agitating, stirring, or otherwise having all facets of the particles accessible to the precursors for at least some time during the exposure steps.

According to some embodiments of the present invention, each of the exposure steps is flowed by an intermediate exposure step, wherein the particles are exposed to an oxygen precursor that modifies the top atomic layer so as to allow a more uniform deposition of the following precursor. Hence, according to some embodiments, the ALD process further includes exposing the material to water and/or ozone after each of Step (i) and Step (ii). Without being bound by any particular theory, it is assumed that ozone breaks down the organo-metallic residues on the top atomic layer on the particles after exposing the particles to the metal precursor, thereby activating the top atomic surface prior to the next deposition step. Similarly, it is assumed that ozone breaks the organic carbon-hydride chains after the exposure of the top atomic layer to the fluoride precursor, creating free radicals and activating the surface in preparation for the next exposure to the metal precursor.

While the ALD process, used in the context of some embodiments of the present invention, is based on the well-known and generally practiced ALD technique, some features of the technique confer advantageous properties to the metal fluoride coated particulate lithium intercalation material, as provided herein.

For example, using particulate material and moving the particles with respect to themselves during the deposition process allows the formation of a uniform layer substantially all over the gas-accessible surface of the particles. In contrast, coating pre-formed objects (an electrode) made from pristine (uncoated) particles by ALD is disadvantageous due to factors associated with diffusion of the ALD-precursor vapors. Without being bound by any particular theory, it is assumed that ALD-precursor vapors diffusion inside a pre-formed electrode is different from the diffusion to and out the gas-accessible surfaces of suspended particles; it is assumed that in a pre-formed electrode the ALD-precursor vapors would not reach all gas-assessable surfaces evenly and would not be fully flushed (removed) from the inner parts of the pre-formed electrode during the step of flushing excess precursor, and would be trapped inside pores, nooks and crevices of the pre-formed electrode. The remaining precursor would react with the other precursor uncontrollably and as a result, the electrode pores would be filled and clogged with metal fluoride deposits, and a substantial part of the internal electrode surface would not be coated with ALD-type metal fluoride layer.

For another example, since the process is used to coat particles before they are used to form an electrode, the process is not limited in the variety of the metal or fluoride precursors which may be employed in the ALD process, and thus there is no limitation in the variety of possible metal fluoride composition that can be deposited on the particles. The process can therefore be effected at relatively high temperatures (i.e., higher than 200° C., higher than 250° C., higher than 275° C. , higher than 300° C. or higher than 400° C.).

The freedom to use high temperatures in the formation of the metal fluoride layer provides yet another advantage of the present invention, in the form of the ability to improve the stability and effectiveness of the metal fluoride layer on the surface of the particles. As known in the art, thermal treatment of layers deposited by ALD is an optional step in the process, which is effected in order to modify the layer's morphology from amorphous to more crystalline, rendering the deposited layer more stable.

Hence, according to some embodiments of the present invention, the ALD process further includes an optional step of heating the metal fluoride layer to relatively high temperatures, referred to herein as “optimizing temperature”.

For example, the metal fluoride layer is heated to an optimizing temperature that is higher than 200° C., higher than 250° C., higher than 275° C., higher than 300° C. or higher than 400° C. It is noted that the optional thermal treatment can be effected after forming each atomic period, or after forming any number of atomic periods, or after forming the entire uniform metal fluoride layer on the surface of the particles.

According to some embodiments of the present invention, the metal precursor can be any metal source known in the art as suitable for an ALD process. Non-limiting examples of metal sources include HF and pyridine HF metal salts, bis-ethyl-cyclopentadienyl-magnesium, bis(pentamethylcyclopentadienyl)magnesium (C₂₀H₃₀Mg), bis(6,6,7,7,8,8,8,-heptafluoro-2,2-dimethyl-3,5-octanedionate)calcium (Ca(OCC(CH₃)₃CHCOCF₂CF₂CF₃)₂), bis(cyclopentadienyl)zirconium(IV) dihydride (C₁₀H₁₂Zr), dimethylbis(pentamethylcyclopentadienyl)zirconium(IV), bis(pentafluorophenyl)zinc ((C₆F₅)₂Zn), diethylzinc ((C₂H₅)₂Zn), triisobutylaluminum ([(CH₃)₂CHCH₂]₃Al) and tris(2,2,6,6-tetramethyl-3,5-heptanedionate)aluminum (Al(OCC(CH₃)₃CHCOC(CH₃)₃)₃).

According to some embodiments of the present invention, the fluoride precursor can be any fluoride source known in the art as suitable for an ALD process. Non-limiting examples of fluoride sources include HF, pyridine HF, hexafluoroacetylacetonate, TaF₅, TiF₄, and the like.

According to an aspect of some embodiments of the present invention, there is provided a method of reducing the charge/discharge capacity fade rate of a rechargeable lithium-ion battery having an electrode. The method is carried out by coating a particulate lithium intercalation material used in the making of the electrode, with a uniform layer of a metal fluoride to thereby form a metal fluoride coated particulate lithium intercalation material, and forming the electrode from the coated particulate lithium intercalation material.

Accordingly, there is provided a lithium intercalation electrode which is constructed using a particulate lithium intercalation material coated with a layer of a metal fluoride, according to embodiments of the present invention.

The method of reducing the charge/discharge capacity fade rate and the making of the electrode further includes the use of other electrode forming elements and substances, such as a current collector, which is typically a highly conductive solid element, and a binder substance for casting the electrode on the current collector.

Current collectors are typically made of a metal, and shaped to have a large surface area, namely a thin foil, a grid/mesh and the like.

Binder substances include, without limitation, organic resins and compressible carbon allotropes. Organic resins include various polyvinylidene fluoride (PVDF) resins, which are soluble in organic solvents, and various modified styrene butadiene rubbers (SBR), which are soluble in aqueous solutions.

Embodiments of the present invention encompass both lithium intercalation cathodes and anodes, as it is advantageous to coat both types of electrodes by a uniform layer of a metal fluoride, as presented herein. A LIB, having at least one electrode that includes a particulate lithium intercalation material coated with a uniform layer of a metal fluoride, is expected to exhibit improved performance in terms of the charge/discharge capacity fade rate.

Thus, according to an aspect of some embodiments of the present invention, there is provided a rechargeable lithium-ion battery (LIB), which includes at least:

a cathode, an anode, a separator, and an electrolyte that comprises lithium ions, wherein at least one of the cathode and/or anode includes a particulate lithium intercalation material coated with a layer of a metal fluoride according to embodiments of the present invention.

In some embodiments, the LIB includes a cathode made using a particulate lithium intercalation material coated with a layer of a metal fluoride according to embodiments of the present invention.

In some embodiments, the LIB includes an anode made using a particulate lithium intercalation material coated with a layer of a metal fluoride according to embodiments of the present invention.

In some embodiments, both the cathode and the anode of the LIB are each individually made using a suitable particulate lithium intercalation material coated with a layer of a metal fluoride according to embodiments of the present invention.

As demonstrated in the Examples section, a uniform layer of magnesium fluoride over the surface of LiMn_{1.5}Ni_{0.5}O₄ (LMNO) particles, characterized by 6, 12 and 25 atomic periods of the metal fluoride, was successfully formed using ALD-technique. The present inventors have also constructed a lithium intercalation cathode from the MgF₂ coated LMNO particles and tested the charge/discharge capacity fade rate in a rechargeable lithium-ion battery, compared to that observed in a lithium-ion battery using a cathode constructed from uncoated LMNO particles. The results have shown that the uniform layer of the metal fluoride, coating the LMNO particles, reduced the fade rate significantly.

The structural and chemical fingerprints of particles of a lithium intercalation material, which have been coated with a uniform layer of a metal fluoride according to some embodiments of the present invention, can be expressed by the amount of elements of the lithium intercalation material that leak into an electrolyte when exposed thereto. Such fingerprints can be used to distinguish between a composition-of-matter comprising a particulate lithium intercalation material coated with a layer of a metal fluoride, as provided herein, and a composition-of-matter comprising any other lithium intercalation material, pristine or coated according to techniques known in the art.

Thus, a composition-of-matter comprising a particulate lithium intercalation material, coated with a layer of a metal fluoride according to some embodiments of the present invention, is characterized a low level of leakage of elements from the lithium intercalation material to an electrolyte when exposed to the electrolyte. According to some embodiments, the level of leakage is low compared to the level of leakage from uncoated particulate lithium intercalation material, or compared to the level of leakage from particulate lithium intercalation material coated with a substance other than metal fluoride, or compared to the level of leakage from particulate lithium intercalation material coated with a non-uniform layer of a metal fluoride.

In some embodiments of the present invention, the level of leakage of elements from the lithium intercalation material to an electrolyte when exposed to the electrolyte, is expressed by the concentration of one or more of the lithium intercalation material elements in the electrolyte prior to and after exposure of a composition-of-matter comprising the lithium intercalation material of interest to the electrolyte. According to some embodiments, the level of leakage is expressed as the difference in the concentration of an element in the electrolyte prior to and after exposure thereto and/or after the electrolyte has been used in a cell comprising the tested particulate lithium intercalation material for a given number of charge/discharge cycles; such level of leakage is expressed in leakage percent, or leakage % at a given temperature.

In some embodiments of the present invention, the level of leakage of a composition-of-matter comprising a particulate lithium intercalation material coated with a layer of a metal fluoride according to embodiments of the present invention, is less than 20 leakage %, less than 15 leakage %, less than 10 leakage %, less than 5 leakage % or less than 1 leakage % at a given temperature.

The structural and chemical fingerprints of particles of a lithium intercalation material, which have been coated with a uniform layer of a metal fluoride according to some embodiments of the present invention, can also be expressed by the reduction in the charge/discharge capacity fade rate, as defined herein. According to some embodiments, the fade rate is low compared to the fade rate exhibited by uncoated particulate lithium intercalation material, or compared to the fade rate exhibited by particulate lithium intercalation material coated with a substance other than metal fluoride, or compared to the fade rate exhibited by particulate lithium intercalation material coated with a non-uniform layer of a metal fluoride. It is noted that the fade rate is correlated to the working temperature, namely to the temperature of the system used to measure the charge/discharge capacity.

In some embodiments of the present invention, a charge/discharge capacity fade rate can be expressed as the reduction in charge/discharge capacity per one charge/discharge cycle, expressed in mAh/gram. In some embodiments of the present invention, a charge/discharge capacity fade rate can be expressed as the reduction in discharge capacity in percent mAh/gram after 30 charge/discharge cycles at a given temperature under specified electrochemical conditions.

It is expected that during the life of a patent maturing from this application many relevant methods, uses and compositions will be developed and the scope of the terms methods, uses, compositions, batteries and devices are intended to include all such new technologies a priori.

As used herein throughout, and for any one of the embodiments described herein, the term “about” refers to ±10%.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the phrase “substantially devoid of” a certain substance refers to a composition that is totally devoid of this substance or includes no more than 0.1 weight percent of the substance.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The words “optionally” or “alternatively” are used herein to mean “is provided in some embodiments and not provided in other embodiments”. Any particular embodiment of the invention may include a plurality of “optional” features unless such features conflict.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

As used herein the term “method” refers to manners, means, techniques and procedures for accomplishing a given task including, but not limited to, those manners, means, techniques and procedures either known to, or readily developed from known manners, means, techniques and procedures by practitioners of the chemical, pharmacological, biological, biochemical and medical arts.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non-limiting fashion.

### Example 1

### MgF₂ Coated Spinel-Type Cathode Material

Below is an exemplary process for coating raw particulate lithium intercalation material which results in all-around coated particles, namely particles which are coated with a metal fluoride evenly and uniformly from all sides. The process does not alter the macroscopic structure of the particulate lithium intercalation material; hence, agglomerates and fused-together particles are treated as an individual entity with respect to their coated surface.

Powder coating by ALD became possible by a uniquely developed fluidized bed reactors (FBR). In such FBR reactor, the powder particles are floated in the chamber by means of a flow of an inert gas (i.e., dry nitrogen) jetted towards the sample from below. The gas jet is effected in order to move the particles with respect to themselves just before the precursors are introduced into the chamber.

Materials and Methods:

The active spinel-type cathode material, LiMn_{1.5}Ni_{0.5}O₄ (LMNO) partially agglomerated powder, characterized by an individual particle size of about 100 nm in diameter, was obtained from Zentrum für Sonnenenergie and Wasserstoff-Forschung Baden-Württemberg.

Bis-ethyl-cyclopentadienyl-magnesium (Mg(EtCp)₂), used as a source (precursor) of magnesium for ALD, was obtained from Strem Chemicals Inc.

Hexafluoroacetylacetonate (Hfac), used as a source of fluorine for ALD, was obtained from Sigma Aldrich.

Atomic layer deposition was performed in an ALD fluidized bed reactor (ALD-FBR), model TFS-200 by Beneq Oy, Espoo, Finland.

Briefly, 10-20 grams of pristine LMNO powder was loaded into the ALD chamber for each deposition batch, and the chamber was heated up to about 275° C. prior to starting the deposition cycles. The ALD system reactor was then evacuated to a base pressure of about 3 mbar. Each deposition cycle included four sequential steps separated by nitrogen purge step for avoiding undesired chemical reactions between the precursors inside the chamber. Each deposition cycle added one atomic period of the magnesium fluoride onto the surface of the particulate LMNO.

The first step included magnesium deposition. The Mg precursor was introduced into the ALD chamber in a nitrogen carrier under pulse mode: Mg(EtCp)₂ was heated to 80-90° C. prior to the process to obtain sufficient partial pressure, and thereafter a full coverage of the Mg layer was achieved on the surface of the particulate LMNO powder using a number of pulses, and the system was purged by nitrogen gas.

The second step included exposure of the substrate (i.e. particulate LMNO) to ozone in order to break down the organo-metallic residues and to activate the surface prior to the next deposition step.

The third step included exposure of the substrate to the fluorine precursor, hexafluoroacetylacetone (Hfac), which was introduced in a constant flow mode for several seconds; the Hfac precursor was cooled down to 20° C. to maintain constant partial pressure through the deposition.

The fourth step included exposure of the particulate LMNO to ozone flow, which breaks the organic carbon-hydride chains creating free radicals and activating the surface in preparation for the next cycle repeating of the Mg—F deposition steps presented above.

During the steps of exposing the LMNO particles to the source materials, the particles were agitated and moved with respect to themselves by means of a flow of nitrogen gas just before each pulse of a precursor to ensure that the deposition of metal or fluoride is essentially uniform over the entire surface of the particles.

In order to form a layer having more than one atomic period, the four steps described above were repeated according to the desired number of atomic periods.

The LMNO particles were analyzed using high resolution scanning electron microscopy (HRSEM, Zeiss) operated at acceleration voltage of 4 kV. The surface of pristine and coated LMNO particles was compared using HRSEM in high magnifications to verify coating uniformity on the different particle facets, and over the coated particles.

Samples for transmission electron microscopy (TEM) analysis were prepared by suspending the particles in ethanol and spraying the suspension on holey carbon coated TEM copper grid. Bright field TEM images were collected to verify layer continuity across single particles and agglomerates outer surfaces. High resolution TEM images were acquired to measure the deposited layer thickness and its uniformity based on the contrast between the particle's crystalline lattice and the amorphous morphology of the deposited metal fluoride layer. The layer's chemical composition was measured using scanning transmission electron microscopy energy dispersive spectroscopy (STEM/EDS) detector. All TEM related work was carried out using FEI Tecnai field emission gun F20 machine operated at 200 kV.

Results:

In order to measure accurately the metal fluoride layer's thickness, the inspected particles were positioned as close as possible to zone axis (“high-symmetry” orientation) in order to observe the actual thickness of the layer. The thickness of the metal fluoride later was determined by averaging at least 10 measurement points at different locations on each observed particle.

The LiMn_{1.5}Ni_{0.5}O₄ particles were coated with 6, 12 and 25 atomic periods of magnesium fluoride, each afforded by alternating exposure to Mg and F, wherein each atomic period is characterized by a periodic tenuity (thickness) of about 5.8 Å, or 0.58 nm per ALD cycle. It is noted that this periodic tenuity is larger than the typical value obtained by ALD method on flat surfaces in general [Hwang, C. S. et al., Atomic layer Deposition for Semiconductors, Springer, New York, USA, 2014; Liang, X. et al., J Am Ceram Soc, 2007, 90:57-63; and Hakim, L. F. et al., Nanotechnology, 2005, 16:S375-S381].

FIG. 1 is a bright field TEM electron-micrograph of a cross-sectional view of a LiMn_{1.5}Ni_{0.5}O₄ particle coated with a uniform layer of MgF₂ comprising 12 atomic periods using an ALD process.

As can be seen in FIG. 1, the TEM analysis shows the uniformity and evenness of the coating MgF₂ layer, being devoid of humps, gaps and holes. The magnesium fluoride layer thickness measurements demonstrate a relative standard deviation of the coat's thickness in nanometer as being about 8.2%.

STEM/EDS elemental analysis, obtained from the surface of the MgF₂ coated LiMn_{1.5}Ni_{0.5}O₄ particles, indicated a constant stoichiometric elemental ratio, as can be seen in Table 1.

TABLE 1

| | Mass | Atomic |
|---|---|---|
| Element | content (%) | content (%) |
| F | 69.1 | 74.1 |
| Mg | 30.9 | 25.9 |
| Total | 100 | 100 |

### Example 2

### Performance of Spinel-Type Cathode Material Coated with MgF₂

Materials and Methods:

A lithium intercalation cathode was prepared using the MgF₂-coated LMNO particles, prepared as described hereinabove and a conductive carbon black as an additive for LIB, and a resin binder.

Briefly, a slurry of the coated LMNO particles was prepared by mixing of 80 wt. % coated LMNO particles, 10 wt. % C-Nergy™ Super C45 (TIMCAL LTD, Bodio, Switzerland), 10 wt. % Kynar® PVDF resin (Arkema S.A., France) and N-methyl-2-pyrrolidone (NMP) as a solvent. The slurry was prepared by overnight component stirring using a magnetic stirrer, and was visually uniform before use. Thereafter the cathode sheet was prepared by casting the slurry on a top of aluminum foil current collector with doctor blade, followed by drying and thermo-treatment.

Discs of ½ inch in diameter were cut out from the above-described cathode sheet and assembled into T-type cells (Entegris, Inc., Billerica, Mass., USA) with Li-metal counter-electrodes (anodes). The working electrode (cathode) and counter-electrode were separated with Whatman filter paper, and the cell was filled with an electrolyte (1 M LiPF₆ dissolved in ethylene carbonate/dimethyl carbonate (EC/DMC) mixture of 1:1 vol. ratio (Alfa Aesar)). The cathode loading was between 6.5 and 8 mg/cm² of the coated cathode material.

The discharge/recharge cycling was conducted using Arbin BT2000 in galvanostatic mode (the current was 0.1 mA/cm²), voltage swap between 4.95 and 3.5 V vs. Li/Li⁺.

Results:

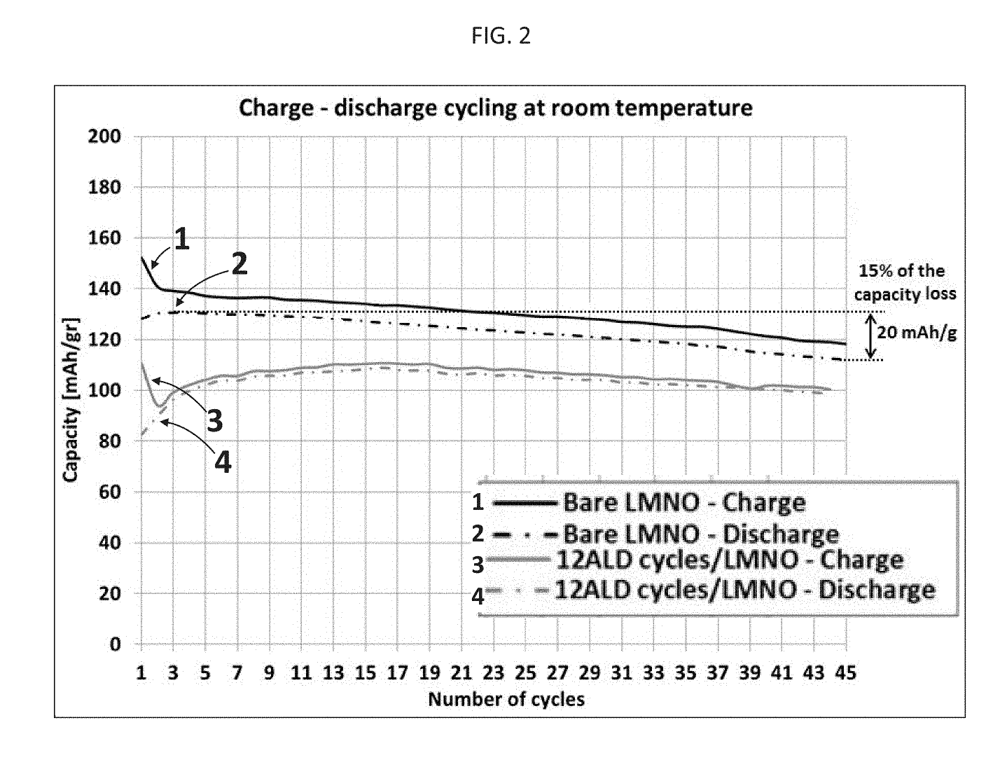

FIG. 2 presents a comparative plot of the charge/discharge capacity of a cathode made with particles of LiMn_{1.5}Ni_{0.5}O₄ as a function of the number of charge/discharge cycles determined in the above-described test cell at room temperature. Curve 1 represents the charge capacity of the cathode made with pristine (uncoated) particles, Curve 2 represents the discharge capacity of the cathode made with pristine particles, Curve 3 represents the charge capacity of the cathode made with LiMn_{1.5}Ni_{0.5}O₄ particles coated with 12 atomic periods of MgF₂ using ALD, according to some embodiments of the present invention, and Curve 4 represents the discharge capacity of the same cathode made with coated particles.

As can be seen in FIG. 2, the cathode made with uncoated particles exhibits substantial capacity fade (15% during the first 45 cycles), while the cathode made with coated particles exhibit insignificant capacity fade.

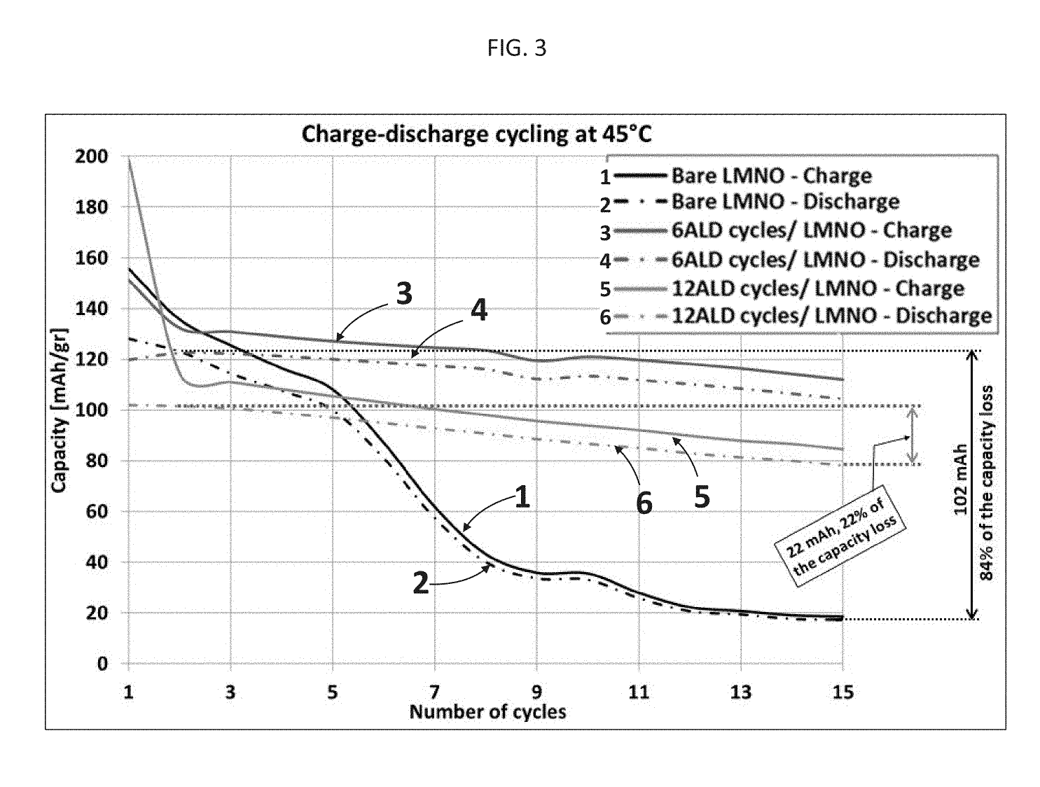

As can be seen in FIG. 3, the uncoated (reference) cathode exhibited a high capacity fade rate during discharge/recharge cycling by losing about 15% of its charge/discharge capacity over 45 discharge/recharge cycles, while the same cathode material, coated with MgF₂ by ALD, according to some embodiments of the present disclosure, exhibited a remarkably low capacity fade rate during discharge/recharge cycling, losing insignificant charge/discharge capacity over at least 45 discharge/recharge cycles.

FIG. 3 presents a plot of charge/discharge capacity of a cathode made with LiMn_{1.5}Ni_{0.5}O₄ particles as a function of the number of charge/discharge cycles at 45° C., wherein Curve 1 represents the charge capacity of a cathode made with pristine (uncoated) particles, Curve 2 represents the discharge capacity of the cathode made with pristine particles, Curve 3 represents the charge capacity of a cathode made with particles coated with 6 atomic periods of MgF₂ using ALD, according to some embodiments of the present invention, Curve 4 represents the discharge capacity of the same coated cathode material, Curve 5 represents the charge capacity of the cathode material coated with 12 MgF₂ by ALD according to some embodiments of the present invention, and Curve 6 represents the discharge capacity of the same cathode made with coated particles.

As can be seen in FIG. 3, the protective effect of the metal fluoride layer is substantially more pronounced at elevated temperature compared to that demonstrated at room temperature (FIG. 2), as the uncoated cathode material exhibits 84% fade of the initial capacity after the first 15 cycles, while the coated material exhibits only 22% of capacity fade.

### Example 3

### Electrolyte Effect on Cathode Material Coated with MgF₂

The following experimental procedure was used to determine the level of leakage of elements from a lithium intercalation material to an electrolyte when exposed to the electrolyte under certain working conditions.

Materials and Methods:

The electrolyte effect on examples of particulate lithium intercalation material, LiMn_{1.5}Ni_{0.5}O₄, (MNS) and LiNi_{1/3}Mn_{1/3}Co_{1/3}O₂ (NMC) powder, uncoated or coated with 6 or 12 atomic periods of MgF₂, according to some embodiments of the present invention, was tested by analyzing the chemical composition of the electrolyte taken from cells, as described hereinabove, after the cells exhibited no change in the charge/discharge capacity (used-up cells).

Electrolyte samples were taken from each cell (0.2 ml) and mixed with 10 ml of distilled H₂O and analyzed by inductively coupled plasma mass spectrometry (ICP-MS). The reference sample was the original electrolyte exposed to the particulate lithium intercalation material before charge/discharge cycling, and all other samples were taken from used-up cells.

Results:

Table 2 presents the results of the above-described experimental procedure for testing the level of leakage of elements from LiNi_{1/3}Mn_{1/3}Co_{1/3}O₂ (NMC), an example of a lithium intercalation material, according to some embodiments of the present invention, into an electrolyte when exposed to the electrolyte. The results refer to uncoated particulate lithium intercalation material (“Uncoated NMC”) and particulate lithium intercalation material coated with a uniform layer comprising 12 atomic periods of MgF₂ using ALD (“12 ALD NMC”), according to embodiments of the present invention. The results are presented in terms of manganese and nickel concentration detected in the electrolyte after the specified number of charge/discharge cycles, wherein N/A (under detection level) denotes a concentration below for detection limit of the system.

TABLE 2

| | Working | Number of | Manganese | Nickel |
|---|---|---|---|---|
| Cathode material | temperature | cycles | [mg/l] | [mg/l] |
| Pristine electrolyte | RT | 0 | N/A | N/A |
| Uncoated NMC | RT | 74 | 2.2895 | 0.5955 |
| Uncoated NMC | 45° C. | 16 | 0.161 | 0.5085 |
| 12 ALD NMC | 45° C. | 315 | N/A | N/A |

Table 3 presents the results of the above-described experimental procedure for testing the level of leakage of elements from LiMn_{1.5}Ni_{0.5}O₄, (MNS), an example of a lithium intercalation material, according to some embodiments of the present invention, into an electrolyte when exposed to the electrolyte. The results refer to uncoated particulate lithium intercalation material (“Uncoated MNS”) and particulate lithium intercalation material coated with a uniform layer comprising 6 or 12 atomic periods of MgF₂ using ALD (“6 ALD MNS” and “12 ALD MNS” respectively), according to embodiments of the present invention. The results are presented in terms of manganese and nickel concentration detected in the electrolyte after the specified number of charge/discharge cycles, wherein N/A denotes a concentration below for detection limit of the system (under detection level).

TABLE 3

| | Working | Manganese | Nickel |
|---|---|---|---|
| Cathode material | temperature | [mg/l] | [mg/l] |
| Pristine electrolyte | RT | N/A | N/A |
| Uncoated MNS | RT | N/A | N/A |
| Uncoated MNS | 45° C. | 0.023 | 0.057 |
| 12 ALD MNS | RT | N/A | N/A |
| 12 ALD MNS | 45° C. | N/A | N/A |
| 6 ALD MNS | 45° C. | N/A | N/A |

As can be seen in Tables 2 and 3, the only samples, in which Mn and/or Ni ions leaked into the electrolyte and detected, were those taken from cells using uncoated particulate lithium intercalation material, while particulate lithium intercalation material coated with a uniform layer of a metal fluoride exhibited no leakage of elements from the material, or in other words less than 1 leakage % at any tested temperature.

### Example 4

### ALD Versus Wet-Deposition

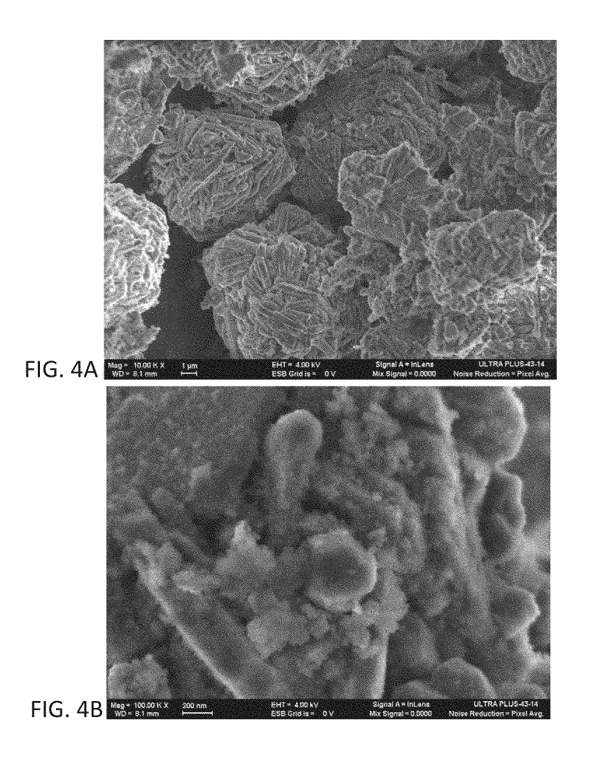

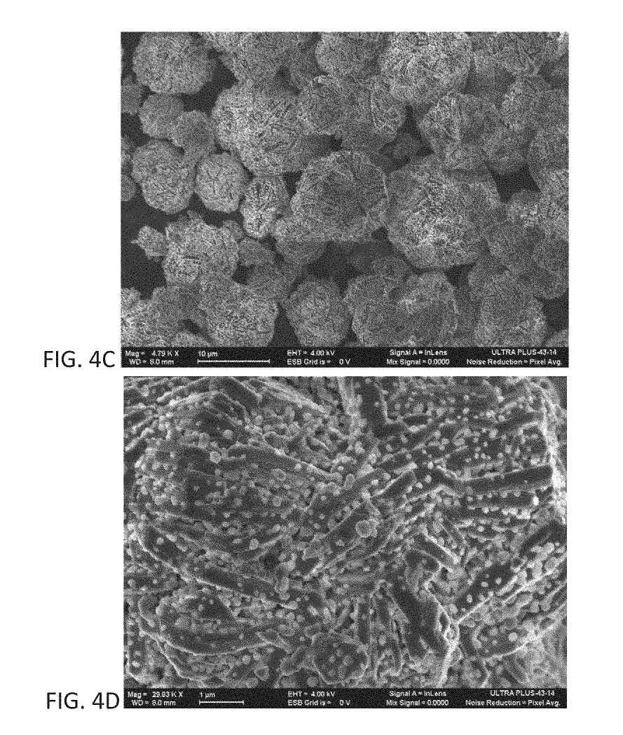

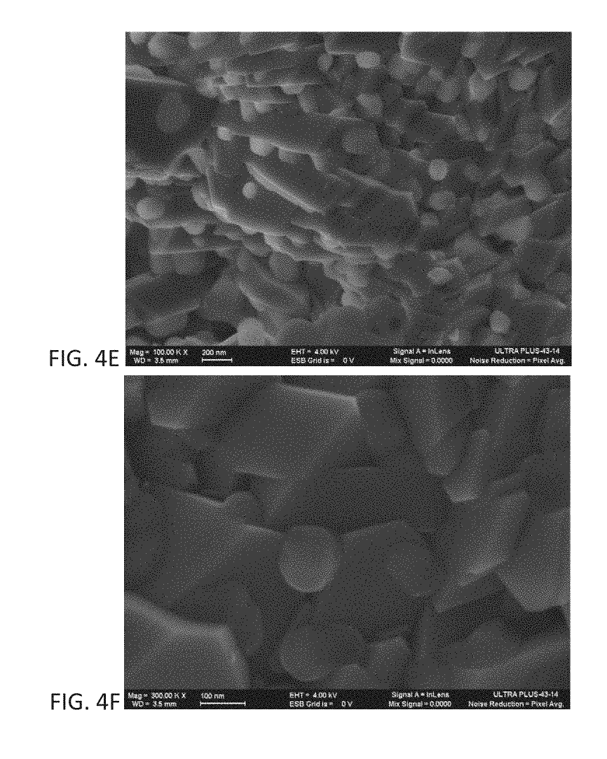

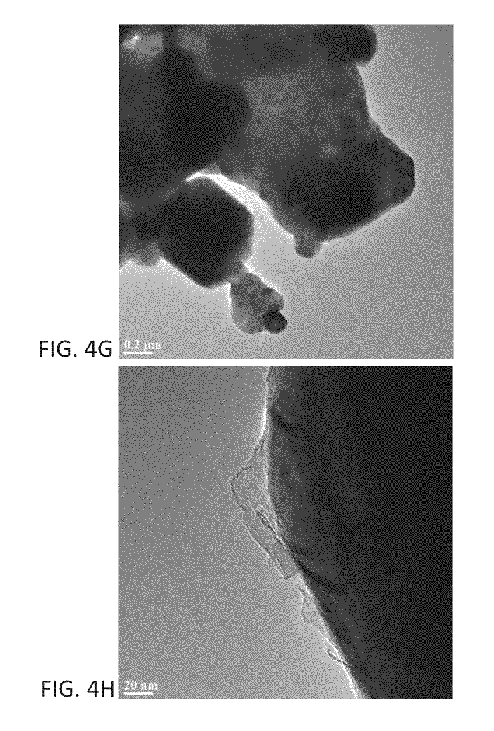

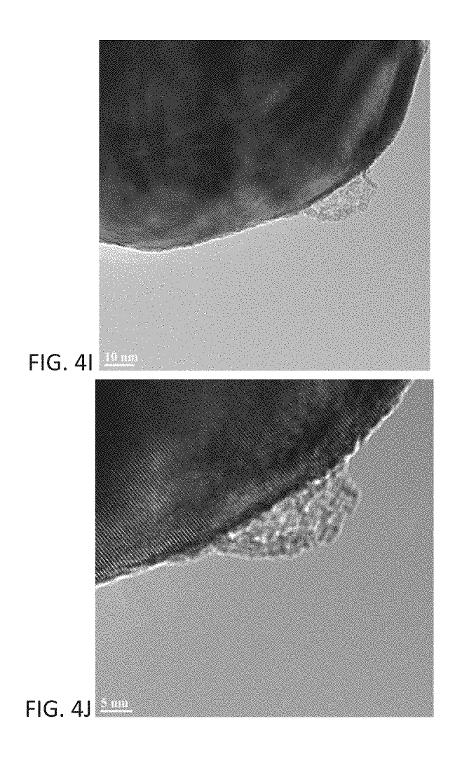

FIGS. 4A-J present HRSEM images of MNS particles coated with MgF₂ (1% by weight) using a wet deposition coating process, wherein FIGS. 4A-B show amorphous and non-uniform MgF₂ coating, FIGS. 4C-D show amorphous and non-uniform MgF₂ coating after heat treatment at 400° C., and FIGS. 4E-J show grains and humps of MgF₂ on the surface of the coated particle.

The following experimental procedure is used to test the effect of the uniformity of the layer of metal fluoride coating lithium intercalation cathode material on the discharge/charge capacity fade rate, as measured in a LIB under certain working conditions. The comparison would test the difference in uniformity of electrode material powder particles coated by wet deposition techniques versus ALD coating.

In order to obtain comparative data, the tests are conducted using particulate lithium intercalation materials coated with a uniform metal fluoride layer by ALD according to embodiments of the present invention, particulate lithium intercalation materials coated with metal fluoride by wet deposition techniques, and a preformed electrode coated with a metal fluoride layer by ALD and comprising binder-bound pristine particulate lithium intercalation materials.

Materials and Methods:

In order to prepare MgF₂-coated particulate lithium intercalation materials by wet deposition methods, a procedure is used as described elsewhere [Wang, Y. et al., J. Solid State Electrochem, 2012, 16:2913-2920; Yunjian, L. et al., Journal of Ionics, 2013, 19:1241-1246; Sang-Hyuk Lee, S. H et al., Journal of Power Sources, 2013, 234:201-207; Wu, Q. et al., Electrochimica Acta, 2015,158:73-80; Wang, H. et al., Solid State Ionics, 2013, 236:37-42; Li, Y. et al., Trans. Nonferrous Met. Soc. China, 2014, 24:3534-3540; Lian, F. et al., Journal of Alloys and Compounds, 2014, 608:158-164; Lee, H. J. et al., Nanoscale Research Letters, 2012, 7:16; Rosina, K. J. et al., J. Mater. Chem., 2012, 22:20602-2061; and Lu, C. et al., Journal of Alloys and Compounds, 2015, 634:75-82].

Briefly, NH₄F and MgCl₂ are dissolved separately in distillated water. A sample of a particulate lithium intercalation cathode material is inserted into the MgCl₂ solution with continuous stirring. NH₄F solution is then added into the solution slowly (titration-like process). The weight ratio between MgF₂ and the cathode powder is chosen to be in the range of 0.5-5.0 wt. %. Follow this titration process, the solution is mixed constantly at room temperature for at least 5 hours, followed by filtration. The powder is then dried for 5 hours at 400° C. to remove the access water and obtain the particulate lithium intercalation cathode material coated by MgF₂ layer.

The same procedure is suitable for AlF₃ coating, by replacing MgCl₂ with Al(NO₃)₃.

In order to compare the results of the wet-deposition to the results of the ALD coating on particulate lithium intercalation cathode materials, the following tests are performed:

Particulate lithium intercalation cathode materials are coated by wet and ALD techniques, and used to construct cells as described hereinabove, which are identical apart for the material used to make the cathode.

The charge/discharge capacity fade rate is measured as described hereinabove for a given number of cycles at room temperature and 45° C. (or other temperatures).

Levels of leakage of cathode material elements into the electrolyte before and after use of the cells are measured by ICP-MS as described hereinabove.

Levels of leakage of cathode material elements into the electrolyte after extended storage periods (several weeks without using the cells) are measured by ICP-MS as described hereinabove.

Metal fluoride layer uniformity are characterized and measured using HRTEM images.

Coating a pre-casted electrode comprising pristine (uncoated) particulate lithium intercalation material, may be effected for an analytical comparisons with an electrode made from pre-coated particulate lithium intercalation material according to some embodiments of the present invention.

In order for this comparative testing to be possible, a cathode material binder substance that can sustain ALD process temperatures (typically 250° C.) should be used. In addition, for coating a pre-casted electrode by wet deposition techniques, the deposited metal fluoride should be prevented from coating the current collector so as to prevent degradation in the cell's performance.

### Example 5

### MgF₂ Coating of NMC Particles by ALD

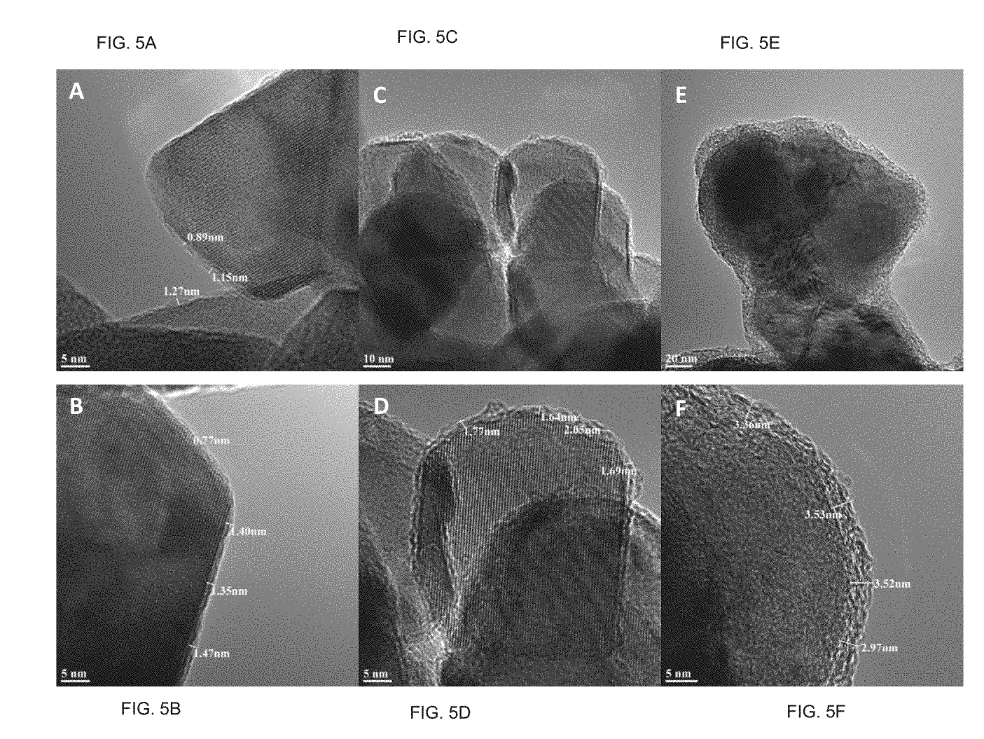

FIGS. 5A-F present bright field TEM electron-micrographs of cross-sectional views of Mn-rich NMC powder particles coated with MgF₂ by ALD process, wherein FIGS. 5A-B show a uniform thickness of about 1.2 nm after 2 ALD cycles, FIGS. 5C-D show s uniform thickness of about 1.8 nm after 4 ALD cycles, and FIGS. 5E-F show a uniform thickness of about 3.4 nm after 6 ALD cycles.

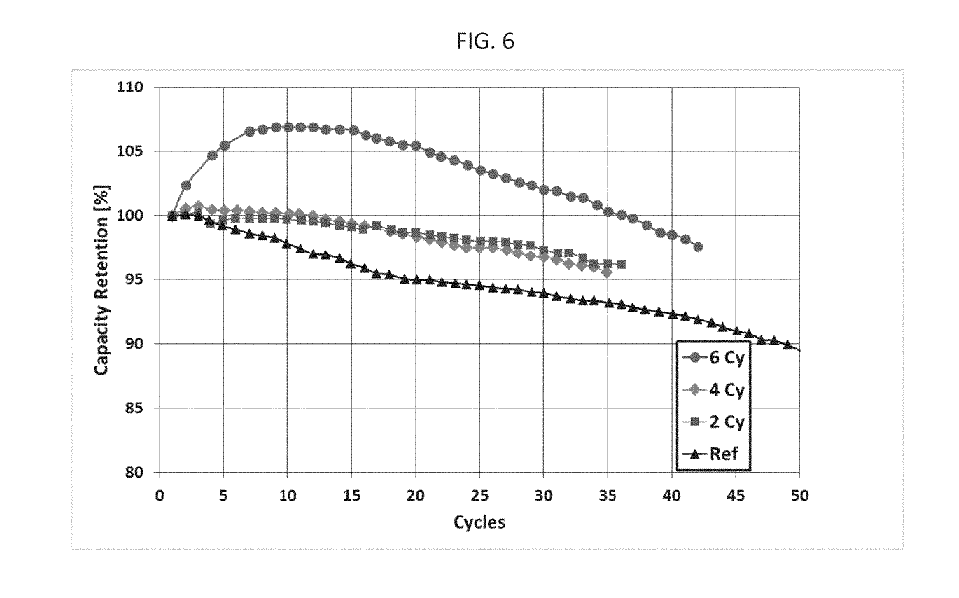

FIG. 6 presents a comparative plot of the charge/discharge capacity as a function of charge/discharge cycles as measured in full cells comprising the particles presented in FIGS. 4A-F normalized against the performance of uncoated particles, showing improved capacity stability of the coated particles compared to the reference.

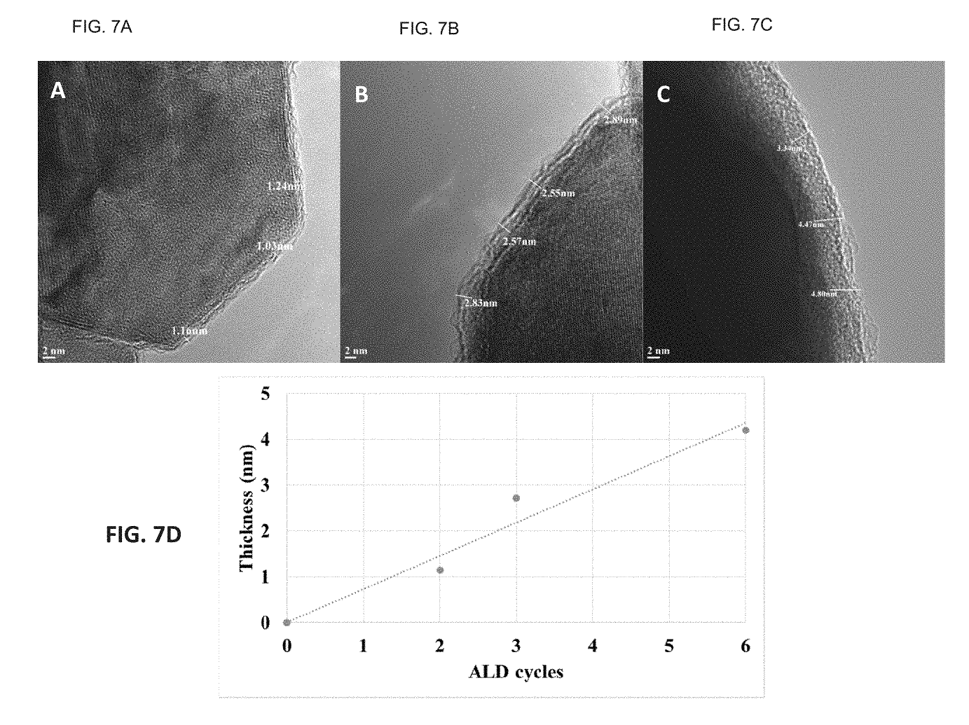

FIGS. 7A-C present bright field TEM electron-micrographs of cross-sectional views of Mn-rich NMC powder particles coated with MgF₂, showing the uniform thickness of the MgF₂ layer after 2 ALD coating cycles (FIG. 7A), after 3 ALD coating cycles (FIG. 7B), after 6 ALD coating cycles (FIG. 7C), and FIG. 7D is a plot of thickness as a function of ALD cycles summarizing the results presented in FIG. 7A-C, showing about 0.7 nm increase in thickness per each ALD cycle.

As can be seem in FIGS. 5A-F and FIGS. 7A-D, in each of the tests a layer of MgF₂ is observed on all sides of the NMC particles, the thickness of which is uniform and magnitude depends on the number of repeated ALD cycles.

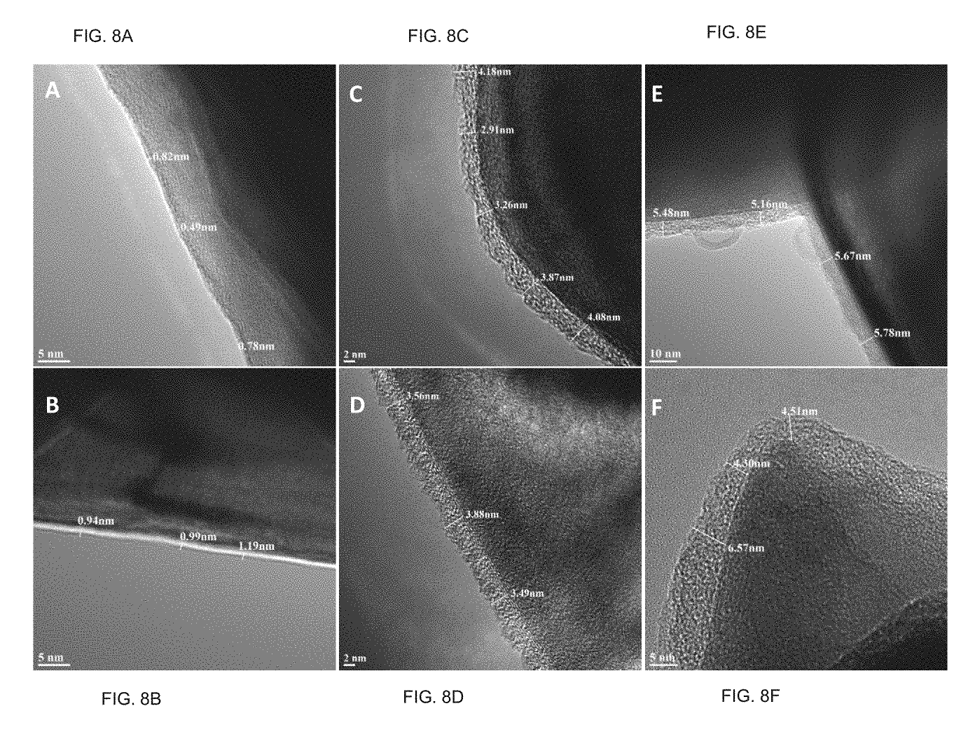

FIGS. 8A-F present bright field TEM electron-micrographs of cross-sectional views of Ni-rich NMC powder particles coated with MgF₂ by ALD process effected at various temperatures, wherein FIGS. 8A-B show a uniform thickness afforded after 2 ALD cycles at 350° C., FIGS. 8C-D show a uniform thickness afforded after 4 ALD cycles at 275° C., and FIGS. 8E-F show a uniform thickness afforded after 6 ALD cycles at 275° C.

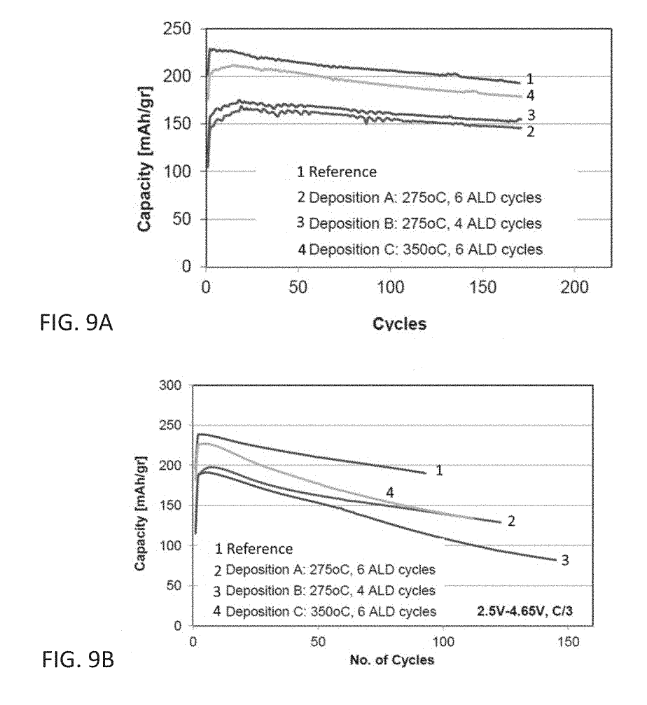

FIGS. 9A-B present comparative plots of charge/discharge capacity as a function of charge/discharge cycles, as measured in cells produced with the coated particles presented in FIGS. 8A-F.

Table 4 presents the results of elemental analysis of the electrolyte of a cell using a MNS electrode after charge-discharge cycling, comparing the electrode dissolution at room temperature and 45° C. of electrodes made with bare MNS particles and MNS particles coated with MgF₂ after 6 or 12 ALD cycles.

TABLE 4

| # | Electrolyte | Temp [° C.] | Mn [mg/l] | Ni [mg/l] |
|---|---|---|---|---|
| 1 | Original | RT | <0.02 | <0.02 |
| 2 | Bare MNS | RT | 0.023 | 0.057 |
| 3 | 12 ALD cycles | RT | <0.02 | <0.02 |
| 4 | 12 ALD cycles | 45° C. | <0.02 | <0.02 |
| 5 | 6 ALD cycles | 45° C. | <0.02 | <0.02 |
| 6 | 12 ALD cycles | 45° C. | <0.02 | <0.02 |

As can be in Table 4, the only cell which electrode has dissolved into the electrolyte during the cycling was built from bare (uncoated) MNS powder, while the electrolyte from coated powder cells showed no traces of Mn and Ni even at elevated temperature (45° C.).

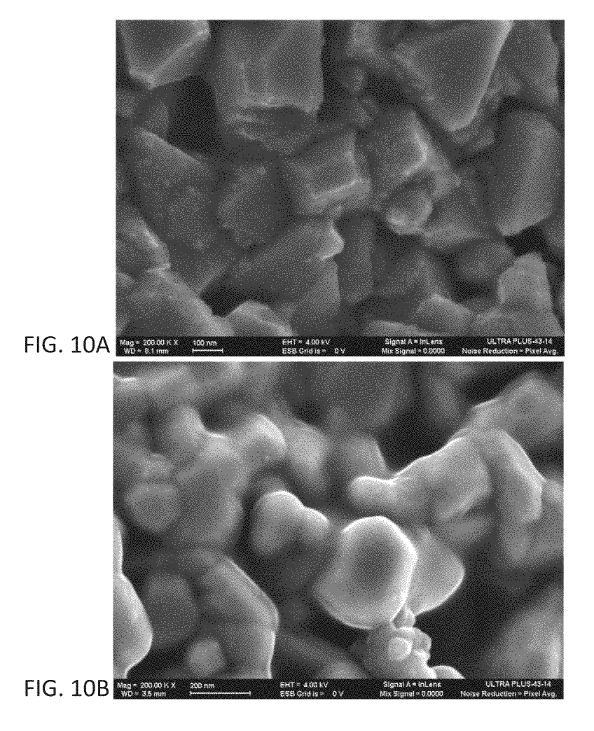

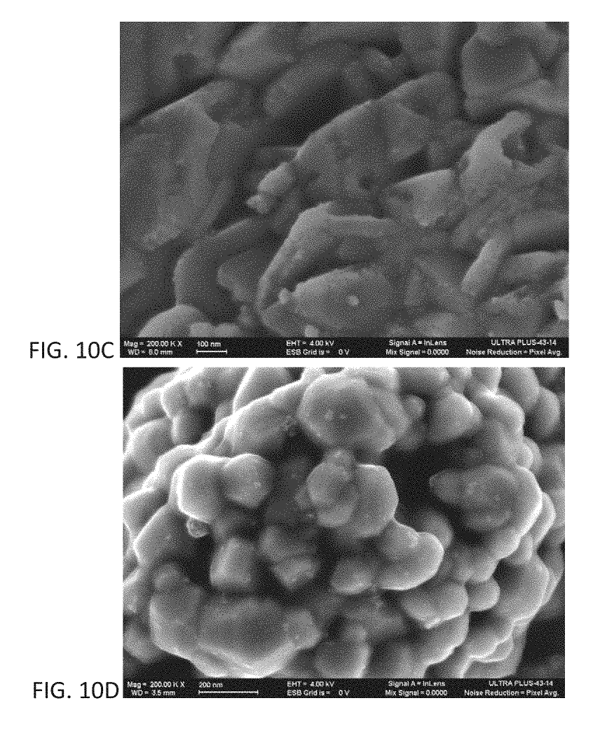

FIGS. 10A-D presents HRSEM images of MNS particles coated with MgF₂ by 6 ALD cycles, taken after the particles were kept in the electrolyte solution for one month at room temperature (FIGS. 10A-B) and for one week at 45° C. followed by 3 weeks at room temperature (FIGS. 10C-D).

As can be seen in FIGS. 10A-D, the uncoated (bare) MNS particles show extensive pitting as a result of the chemical attack by the electrolyte, visible as light-colored spots and extensive roughness on the surface of the particles, while the coated particles show no signs of pitting.

### Example 6

AlF₃ Coating of NMC Particles by ALD

It has been found that aluminum fluoride can be used effectively to protectively coat MNS particles, albeit the coating is finer and not easily observable in scanning electron microscopy.

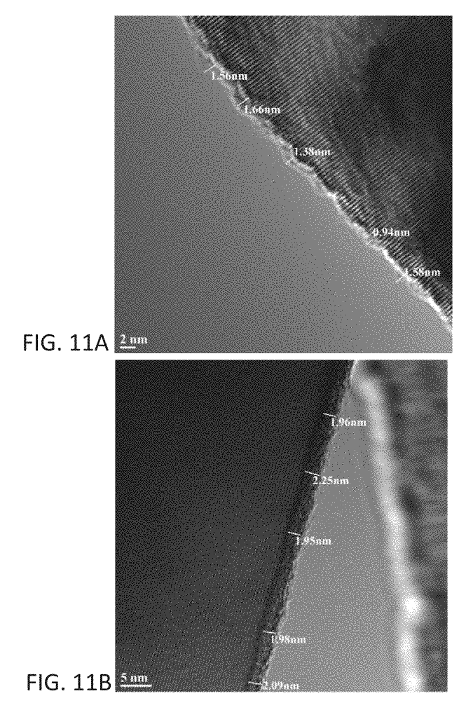

FIGS. 11A-B presents bright field TEM electron-micrographs of cross-sectional views of NMC powder particles coated with AlF₃ by ALD process, wherein FIG. 10A shows a uniform thickness of about 1.5 nm after 6 ALD cycles, and FIG. 10B shows uniform thickness of about 2 nm after 10 ALD cycles.

As can be seen in FIGS. 11A-B, uniform AlF₃ layer depositions were conducted using the ALD technique, and the thickness dependence on the number of cycles has been observed.

While aluminum is not part of the NMS powder composition, it has been identified in elemental analysis of the MNS particle surface after the ALD deposition. Table 5 presents energy-dispersive X-ray spectroscopy (EDS) analysis results of multiple spot measurements taken from NMS particles coated with AlF₃ in 6 ALD cycles at 200° C. As can be seen in Table 5, Al and F were detected in all measurements.

TABLE 5

| Spectrum | C | O | F | Al | Mn | Ni | Total |
|---|---|---|---|---|---|---|---|
| spot 1 | 31.51 | 43.73 | 2.41 | 0.71 | 74.33 | 9.34 | 162.04 |
| spot 2 | 10.61 | 43.65 | 1.28 | 0.82 | 71.01 | 9.23 | 136.59 |
| spot 3 | 10.95 | 43.72 | 1.50 | 0.94 | 66.79 | 8.07 | 131.97 |
| spot 4 | 16.16 | 48.43 | 1.98 | 0.50 | 80.01 | 10.84 | 157.93 |
| spot 5 | 12.70 | 38.89 | 1.54 | 0.62 | 58.60 | 7.82 | 120.16 |
| spot 6 | 13.11 | 46.49 | 1.71 | 0.71 | 67.71 | 9.44 | 139.17 |
| Mean | 15.84 | 44.15 | 1.74 | 0.72 | 69.74 | 9.12 | 141.31 |
| Std. deviation | 7.93 | 3.23 | 0.40 | 0.15 | 7.28 | 1.09 | |
| Max. | 31.51 | 48.43 | 2.41 | 0.94 | 80.01 | 10.84 | |
| Min. | 10.61 | 38.89 | 1.28 | 0.50 | 58.60 | 7.82 | |

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A composition-of-matter comprising a particulate lithium intercalation cathode material coated with a layer of a metal fluoride, wherein:
said layer is characterized by a uniform thickness over at least 75% of the surface of the particulate lithium intercalation material, and/or
said layer is characterized by a uniform thickness over a contiguous area of at least 50 nm² of the surface of the particulate lithium intercalation material; and
said uniform thickness is characterized by at least n atomic periods of the metal fluoride and a deviation of ±m atomic periods, wherein n is an integer greater than 2 and m is 1 for n smaller than 5 or an integer that ranges from 1 to n/5 for n greater than 5; and/or said uniform thickness is characterized by an average thickness of h nanometers and a relative standard deviation of ±k %, wherein h is at least 0.2 and k is less than 20.

2. (canceled)

3. A lithium intercalation cathode comprising the composition-of-matter of claim 1.

4. A rechargeable lithium-ion battery comprising
a cathode,
an anode,
a separator, and
an electrolyte that comprises lithium ions,
wherein
said cathode comprises the composition-of-matter of claim 1.

5. The composition of claim 1, wherein n>5.

6. The composition of claim 1, wherein n≥10 and 1≤m≤n/10.

7. (canceled)

8. The composition of claim 1, wherein h is at least 1 nanometer.

9. The composition of claim 1, wherein h is at least 5 nanometer.

10. The composition of claim 1, wherein k≤10.

11. The composition of claim 1, wherein said metal of said metal fluoride is selected from the group consisting of an alkali metal, an alkali earth metal, a lanthanide and any combination thereof.

12. (canceled)

13. The composition of claim 1, wherein said lithium intercalation cathode material is selected from the group consisting of a layered dichalcogenide, a trichalcogenide, a layered oxide, a spinel-type material and an olivine-type material.

14. The composition of claim 13, wherein said spinel-type material is lithium manganese oxide and/or lithium nickel manganese cobalt oxide.

15. (canceled)

16. The composition of claim 13, wherein said lithium intercalation cathode material is selected from the group consisting of LiMn_{1.5}Ni_{0.5}O₄, LiNi_{1/3}Mn_{1/3}Co_{1/3}O₂, LiMnO₂, LiMn₂O₄ and Li[Li_{0.1305}Ni_{0.3043}Mn_{0.5652}]O₂.

17. (canceled)

18. The composition of claim 1, wherein an average particle size of said particulate lithium intercalation material ranges from 1 nanometers to 600 micrometers.

19. The composition of claim 1, wherein said layer is formed by atomic layer deposition (ALD) process.

20-22. (canceled)

23. A process of coating a particulate lithium intercalation cathode material with a layer of a metal fluoride, the process comprising:
i) exposing particles of the lithium intercalation cathode material to a source of the metal while moving the particles relative to themselves;
ii) exposing said particles to a source of fluoride while moving the particles relative to themselves; and
iii) repeating Step (i) and Step (ii) for n cycles, wherein n≥2.

24. The process of claim 23, wherein the layer of the metal fluoride is characterized by a number of atomic periods of the metal fluoride, and n corresponds to said number of said atomic periods.

25. The process of claim 23, further comprising exposing said particles to water and/or ozone after each of Step (i) and Step (ii).

26. The process of claim 23, further comprising heating said particles to an optimizing temperature.

27. The process of claim 23, wherein said source of said metal is selected from the group consisting of bis-ethyl-cyclopentadienyl-magnesium, bis(pentamethylcyclopentadienyl)magnesium, bis(6,6,7,7,8,8,8,-heptafluoro-2,2-dimethyl-3,5-octanedionate)calcium, bis(cyclopentadienyl)zirconium(IV) dihydride, dimethylbis(pentamethylcyclopentadienyl)zirconium(IV), bis(pentafluorophenyl)zinc, diethylzinc, triisobutylaluminum and tris(2,2,6,6-tetramethyl-3,5-heptanedionate)aluminum.

28. The process of claim 23, wherein said source of fluoride is selected from the group consisting of hexafluoroacetylacetonate, TaF₅ and TiF₄.
